(19) United States
(12) Patent Application Publication
(10) Pub. No.: US 2024/0049571 A1
(43) Pub. Date: Feb. 8, 2024

(54) DISPLAY APPARATUS AND METHOD OF MANUFACTURING THE SAME

(71) Applicant: SAMSUNG DISPLAY CO., LTD., Yongin-si (KR)

(72) Inventors: Hosik SHIN, Yongin-si (KR); Sangwoo KIM, Yongin-si (KR); Gyehwan LIM, Yongin-si (KR)

(21) Appl. No.: 18/229,106

(22) Filed: Aug. 1, 2023

(30) Foreign Application Priority Data
Aug. 4, 2022 (KR) 10-2022-0097575

(51) Int. Cl. H10K 59/80; H10K 59/12

(52) U.S. Cl. CPC H10K 59/873; H10K 59/1201

(57) ABSTRACT

A display apparatus includes a cover window including a window central area, a first window area connected to the window central area in a first direction, a second window area connected to the window central area in a second direction, and a window corner area contacting a corner of the window central area, and a display panel arranged below the cover window. When a radius of curvature of a portion of the display panel arranged to overlap the first window area is R_{B}, and a length of the portion of the display panel arranged to overlap the first window area in a direction perpendicular to a portion of the display panel arranged to overlap the window central area is Z₀, a first width (W_{P1}) of the portion of the display panel in the first direction and arranged to overlap the first window area, satisfies the following equation:

$${W}_{P 1} = \frac{π {R}_{B}}{2} \times \frac{{cos}^{- 1} \frac{{R}_{B} - {Z}_{0}}{{R}_{B}}}{90} .$$

This application claims priority to Korean Patent Application No. 10-2022-0097575, filed on Aug. 4, 2022, and all the benefits accruing therefrom under 35 U.S.C. § 119, the content of which in its entirety is herein incorporated by reference.

### BACKGROUND

### 1. Field

One or more embodiments relate to a display apparatus and a method of manufacturing the display apparatus, and more particularly, to a display apparatus and a method of manufacturing the display apparatus, in which the possibility of generation of defects in a manufacturing process thereof may be reduced and an aesthetic appeal thereof may be improved.

### 2. Description of the Related Art

A display apparatus may include an electronic device, such as a mobile phone or a tablet personal computer (PC), or may be included in an electronic device. The display apparatus may provide visual information, such as an image or a video image, to a user. The display apparatus has been developed to have a structure in which a portion of a display is bent so that an image is displayed on a side surface or a corner of the display apparatus.

### SUMMARY

In a conventional display apparatus, cracks may occur in a display panel thereof in a process of bending the display apparatus.

One or more embodiments include a display apparatus and a method of manufacturing the display apparatus, in which the possibility of generation of defects in a manufacturing process may be reduced and an aesthetic appeal may be improved.

According to one or more embodiments, a display apparatus includes a cover window including a window central area, a first window area connected to the window central area in a first direction and bent based on an axis extending in a second direction crossing the first direction, a second window area connected to the window central area in the second direction and bent based on an axis extending in the first direction, and a window corner area contacting a corner of the window central area, and a display panel arranged below the cover window, where, when a radius of curvature of a portion of the display panel arranged to overlap the first window area and bent based on the axis extending in the second direction is R_{B}, and a length of the portion of the display panel arranged to overlap the first window area in a direction perpendicular to a portion of the display panel arranged to overlap the window central area is Z₀, a first width (W_{P1}) of the portion of the display panel in the first direction arranged to overlap the first window area satisfies the following equation:

$${W}_{P 1} = \frac{π {R}_{B}}{2} \times \frac{{cos}^{- 1} \frac{{R}_{B} - {Z}_{0}}{{R}_{B}}}{90} .$$

In an embodiment, the display panel may include a panel central area, a first panel area connected to the panel central area in the first direction and bent based on the axis extending in the second direction, a second panel area connected to the panel central area in the second direction and bent based on the axis extending in the first direction, and a panel corner area contacting a corner of the panel central area, the window central area may have a rectangular shape having a chamfered vertex, and the panel central area may have a rectangular shape having a chamfered vertex.

In an embodiment, a radius of curvature of the corner of the window central area may be the same as a radius of curvature of the corner of the panel central area.

In an embodiment, the panel central area may be arranged to overlap the window central area, the first panel area may be arranged to overlap the first window area, the second panel area may be arranged to overlap the second window area, and the panel corner area may be arranged to overlap the window corner area.

In an embodiment, the panel central area may be arranged not to overlap the first window area, the second window area, and the window corner area.

In an embodiment, a width of the first panel area in the first direction may be the same as the first width.

In an embodiment, a width of the second panel area in the second direction may be the same as the first width.

In an embodiment, a radius of curvature of the corner of the window central area may be less than a radius of curvature of the corner of the panel central area.

In an embodiment, a portion of the panel central area may be arranged to overlap the window central area, another portion of the panel central area and the first panel area may be arranged to overlap the first window area, another portion of the panel central area and the second panel area may be arranged to overlap the second window area, and the panel corner area may be arranged to overlap the window corner area.

In an embodiment, when the radius of curvature of the corner of the window central area is R_{W}, and the radius of curvature of the corner of the panel central area is R_{P}, a second width (W_{P2}) of a portion of the panel central area protruding more in the first direction than the window central area may satisfy the following equation:

$${W}_{P 2} = {R}_{P} - {R}_{W} - \frac{{R}_{P} - {R}_{W}}{\sqrt{2}} = - ( 1 - \frac{1}{\sqrt{2}} ) {R}_{W} + ( 1 - \frac{1}{\sqrt{2}} ) {R}_{P} .$$

In an embodiment, a width of a portion of the panel central area protruding more in the second direction than the window central area may be the same as the second width.

In an embodiment, a third width W_{P3} of the first panel area in the first direction may satisfy the following equation:

WP₃=W_{P1}−W_{P2}.

In an embodiment, A width of the second panel area in the second direction may be the same as the third width.

In an embodiment, A radius of curvature of a portion of the display panel arranged to overlap the second window area may be the same as R_{B}, a length of the portion of the display panel arranged to overlap the second window area in the direction perpendicular to the portion of the display panel arranged to overlap the window central area may be the same as Z₀, and a width of the portion of the display panel arranged to overlap the second window area in the second direction may be the same as the first width.

According to one or more embodiments, a method of manufacturing a display apparatus includes preparing a cover window and a display panel, bonding a guide film to the display panel, pre-forming the display panel by applying an external force to the guide film, and bonding the cover window to the display panel, where the cover window includes a window central area, a first window area connected to the window central area in a first direction and bent based on an axis extending in a second direction crossing the first direction, a second window area connected to the window central area in the second direction and bent based on an axis extending in the first direction, and a window corner area contacting a corner of the window central area, and the bonding the cover window includes bonding the cover window to the display panel in a way such that, when a radius of curvature of a portion of the display panel arranged to overlap the first window area and bent based on the axis extending in the second direction is R_{B}, and a length of the portion of the display panel arranged to overlap the first window area in a direction perpendicular to a portion of the display panel arranged to overlap the window central area is Z₀, a first width (W_{P1}) of the portion of the display panel in the first direction arranged to overlap the first window area satisfies the following equation:

$${W}_{P 1} = \frac{π {R}_{B}}{2} \times \frac{{cos}^{- 1} \frac{{R}_{B} - {Z}_{0}}{{R}_{B}}}{90} .$$

In an embodiment, the display panel may include a panel central area, a first panel area connected to the panel central area in the first direction and bent based on the axis extending in the second direction, a second panel area connected to the panel central area in the second direction and bent based on the axis extending in the first direction, and a panel corner area contacting a corner of the panel central area, the window central area may have a rectangular shape having a chamfered vertex, and the panel central area may have a rectangular shape having a chamfered vertex.

In an embodiment, the bonding the cover window may include bonding the cover window to the display panel in a way such that, when a radius of curvature of the corner of the window central area is the same as a radius of curvature of the corner of the panel central area, a width of the first panel area in the first direction is the same as the first width.

In an embodiment, the bonding the cover window may include bonding the cover window to the display panel in a way such that a width of the second panel area in the second direction is same as the first width.

In an embodiment, the bonding the cover window may include bonding the cover window to the display panel in a way, such that, when the radius of curvature of the corner of the window central area is R_{W}, and the radius of curvature of the corner of the panel central area is R_{P}, a second width W_{P2} of a portion of the panel central area protruding more in the first direction than the window central area satisfies the following equation:

$${W}_{P 2} = {R}_{P} - {R}_{W} - \frac{{R}_{P} - {R}_{W}}{\sqrt{2}} = - ( 1 - \frac{1}{\sqrt{2}} ) {R}_{W} + ( 1 - \frac{1}{\sqrt{2}} ) {R}_{P} ,$$

and a third width W_{P3} of the first panel area in the first direction satisfies the following equation:

W_{P3}=W_{P1}−W_{P2}.

In an embodiment, the bonding the cover window may include bonding the cover window to the display panel in a way such that a width of a portion of the panel central area protruding more in the second direction than the window central area is the same as the second width, and a width of the second panel area in the second direction is the same as the third width.

### BRIEF DESCRIPTION OF THE DRAWINGS

The above and other features of certain embodiments of the disclosure will be more apparent from the following description taken in conjunction with the accompanying drawings, in which:

FIG. 1 is a schematic perspective view of a portion of a display apparatus according to an embodiment;

FIG. 2A is a schematic cross-sectional view of a display apparatus taken along line A-A′ of FIG. 1;

FIG. 2B is a schematic cross-sectional view of a display apparatus taken along line B-B′ of FIG. 1;

FIG. 2C is a schematic cross-sectional view of a display apparatus taken along line C-C′ of FIG. 1;

FIG. 3 is a schematic plan view of a cover window of a display apparatus according to an embodiment;

FIGS. 4 and 5 are schematic views of a display panel of a display apparatus according to an embodiment;

FIG. 6 is a schematic enlarged plan view of region D of the display panel of FIG. 5;

FIG. 7 is an equivalent circuit diagram of an embodiment of a pixel circuit included in the display apparatus of FIG. 1;

FIG. 8 is a schematic cross-sectional view of the display panel of FIG. 6, taken along line I-I′;

FIG. 9 is a schematic cross-sectional view of the display panel of FIG. 6, taken along line II-II′;

FIG. 10 is a schematic plan view of a display panel of a display apparatus according to an embodiment;

FIG. 11 is a view for describing a first width of a display panel of a display apparatus according to an embodiment;

FIG. 12 is a schematic plan view of a display panel of a display apparatus according to an embodiment;

FIG. 13 is a view for describing a second width of a display panel of a display apparatus according to an embodiment; and

FIGS. 14 to 20C are views for describing a method of manufacturing a display apparatus according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

While the disclosure is capable of various modifications and alternative forms, embodiments thereof are shown by way of example in the drawings and will herein be described in detail. Effects and characteristics of the disclosure, and realizing methods thereof will become apparent by referring to the drawings and embodiments described in detail below. However, the disclosure is not limited to the embodiments disclosed hereinafter and may be realized in various forms.

In embodiments to be described hereinafter, when elements, such as a layer, a film, an area, a plate, etc. are referred to as being “on” another element, the reference may indicate not only a case where the element is “directly on” the other element, but also a case where yet another element is between the element and the other element. Also, for convenience of explanation, elements in the drawings may have exaggerated or reduced sizes. For example, sizes and thicknesses of the elements in the drawings are randomly indicated for convenience of explanation, and thus, the disclosure is not necessarily limited to the illustrations of the drawings.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. In this specification, the expression “A and/or B” may indicate A, B, or A and B. Also, the expression “at least one of A and B” or “at least one selected from A and B” may indicate A, B, or A and B.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

When a certain embodiment may be implemented differently, a specific process order may be performed differently from the described order. For example, two consecutively described processes may be performed substantially at the same time or performed in an order opposite to the described order.

In this specification, a radius of curvature indicates a curvature of a curve or a curved surface, and as the radius of curvature increases, the curvature decreases.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail by referring to the accompanying drawings. In descriptions with reference to the drawings, the same reference numerals are given to components that are the same or substantially the same as each other and any repetitive detailed descriptions thereof may be omitted.

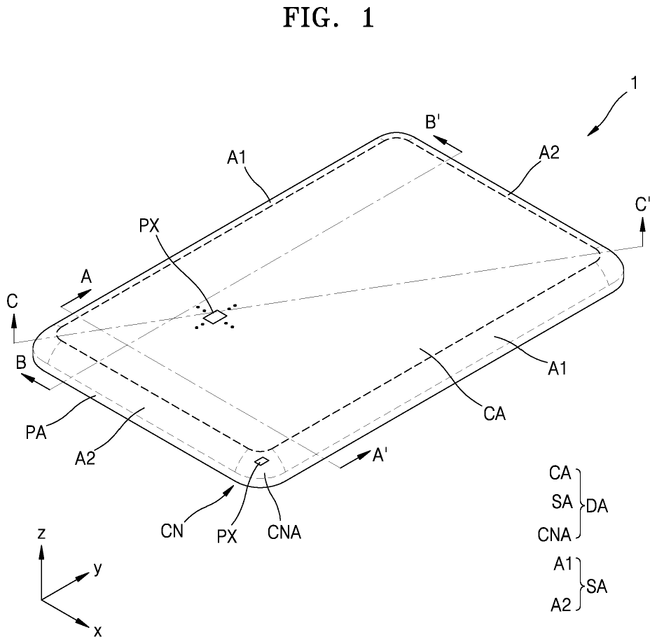

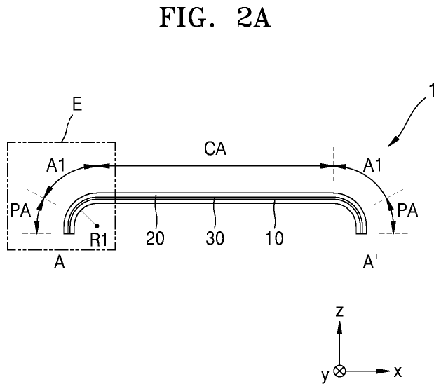

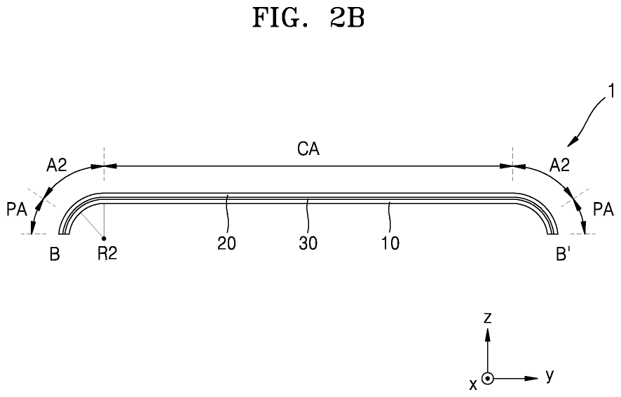

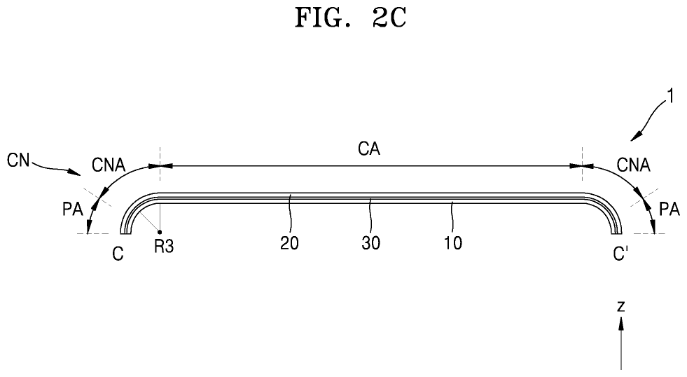

FIG. 1 is a schematic perspective view of a portion of a display apparatus 1 according to an embodiment. FIG. 2A is a schematic cross-sectional view of the display apparatus 1 taken along line A-A′ of FIG. 1, FIG. 2B is a schematic cross-sectional view of the display apparatus 1 taken along line B-B′ of FIG. 1, and FIG. 2C is a schematic cross-sectional view of the display apparatus 1 taken along line C-C′ of FIG. 1.

The display apparatus 1 may be an apparatus for displaying a video image or a still image and may include a portable electronic device, such as a mobile phone, a smartphone, a tablet personal computer (PC), a mobile communication terminal, an electronic notebook, an electronic book, a portable multimedia player (PMP), a navigation device, or an ultra mobile PC (UMPC). However, the display apparatus 1 may also include an electronic device, such as a television, a notebook computer, a monitor, an advertising board, or an Internet of things (IoT) device. Alternatively, the display apparatus 1 may include a wearable device, such as a smartwatch, a watch phone, a glasses-type display, or a head-mounted display (HMD). Alternatively, the display apparatus 1 may be a portion of another device. In an embodiment, for example, the display apparatus 1 may be a display of an electronic device. Alternatively, the display apparatus 1 may be used as: a gauge of a vehicle, a center fascia of a vehicle, or a center information display on a dashboard; a room mirror display substituting a side-view mirror of a vehicle; or a display disposed on a rear surface of a front seat, as an entertainment device for a backseat of a vehicle.

Referring to FIG. 1, an embodiment of the display apparatus 1 which may display an image may have an edge extending in a first direction and an edge extending in a second direction. Here, the first direction and the second direction may cross each other. In an embodiment, for example, the first direction and the second direction may form an acute angle. Alternatively, the first direction and the second direction may form an obtuse angle or a right angle. Hereinafter, embodiments in which the first direction and the second direction are perpendicular to each other will be mainly described, for convenience. Herein, the first direction may be an x direction or a −x direction, and the second direction may be a y direction or a −y direction.

A corner CN, at which the edge extending in the first direction (the x direction or the −x direction) and the edge extending in the second direction (the y direction or the −y direction) meet each other, may have a predetermined curvature.

In an embodiment, as illustrated in FIG. 1, the display apparatus 1 may include a display area DA and a peripheral area PA. The display area DA may include a central area CA, a side area SA, and a corner area CNA.

The central area CA may be arranged at a central portion of the display apparatus 1. The central area CA may be flat. The display apparatus 1 may provide most of the image on the central area CA.

The side area SA may be arranged on a side surface of the display apparatus 1. In an embodiment, the side area SA may be arranged to be adjacent to a side of the central area CA. The side area SA may be bent based on a predetermined axis.

In an embodiment, the side area SA may include a first area A1 and a second area A2. The first area A1 may be adjacent to the central area CA in the first direction (e.g., the x direction or the −x direction). The first area A1 may extend in the second direction (e.g., the y direction or the −y direction). The display apparatus 1 may bend in the first area A1. That is, the first area A1 may be defined as a bending area on a cross-section (e.g., a z-x cross-section) in the first direction, unlike the central area CA. However, the first area A1 may not bend on a cross-section (e.g., a y-z cross-section) in the second direction. That is, the first area A1 may bend based on an axis extending in the second direction.

The second area A2 may be adjacent to the central area CA in the second direction. The second area A2 may extend in the first direction. The display apparatus 1 may bend in the second area A2. That is, the second area A2 may be defined as a bending area on the cross-section (e.g., the y-z cross-section) in the second direction, unlike the central area CA. However, the second area A2 may not bend on the cross-section (e.g., the z-x cross-section) in the first direction. That is, the second area A2 may bend based on an axis extending in the first direction.

The corner area CNA may be arranged at the corner CN of the display apparatus 1. In an embodiment, the corner area CNA may be arranged to be adjacent to a corner of the central area CA. The corner area CNA may bend based on a predetermined axis.

The corner area CNA may at least partially surround the central area CA, the first area A1, and the second area A2. In an embodiment, as described above, where the first area A1 extends in the second direction and bends on the cross-section (e.g., the z-x cross-section) in the first direction, and the second area A2 extends in the first direction and bends on the cross-section (e.g., the y-z cross-section) in the second direction, at least a portion of the corner area CNA may bend on both the cross-section (e.g., the z-x cross-section) in the first direction and the cross-section (e.g., the y-z cross-section) in the second direction. That is, at least a portion of the corner area CNA may be a multi-curved area in which a plurality of curvatures in a plurality of directions overlap one another. The display apparatus 1 may have a plurality of corner areas CNA.

The peripheral area PA may be arranged outside the display area DA. In an embodiment, the peripheral area PA may be arranged on a side surface and a corner of the display apparatus 1 and may surround the display area DA. That is, the peripheral area PA may be arranged outside the first area A1, the second area A2, and the corner area CNA. The peripheral area PA may bend.

As illustrated in FIG. 2A, a portion of the peripheral area PA and the first area A1 may bend by a first radius of curvature R1. As illustrated in FIG. 2B, another portion of the peripheral area PA and the second area A2 may bend by a second radius of curvature R2. However, as illustrated in FIG. 2C, another portion of the peripheral area PA and the corner area CNA may bend by a third radius of curvature R3. Hereinafter, for convenience of explanation, embodiments in which the first radius of curvature R1, the second radius of curvature R2, and the third radius of curvature R3 are the same as one another is mainly described in detail.

A pixel PX may be arranged in the display area DA. In an embodiment, the pixel PX may be arranged in at least one selected from the central area CA, the side area SA, and the corner area CNA. The pixel PX may be realized via a display element. Each pixel PX may include a red sub-pixel, a green sub-pixel, and a blue sub-pixel. Alternatively, each pixel PX may include a red sub-pixel, a green sub-pixel, a blue sub-pixel, and a white sub-pixel. In an embodiment, for example, the plurality of pixels PX may be arranged in the central area CA, the side area SA, and the corner area CNA. Accordingly, the display apparatus 1 may display an image in the central area CA, the side area SA, and the corner area CNA. In an embodiment, the display apparatus 1 may provide a separate image in each of the central area CA, the side area SA, and the corner area CNA. Alternatively, the display apparatus 1 may provide a portion of an image in each of the central area CA, the side area SA, and the corner area CNA.

As described above, the display apparatus 1 may display an image not only in the central area CA, but also in the side area SA and the corner area CNA. Thus, in the display apparatus 1, the display area DA, in which an image is displayed, may be significantly increased. Also, the display apparatus 1 may display an image at the corner CN that is bent, and thus, an aesthetic sense or appeal may be improved.

The pixel PX may not be arranged in the peripheral area PA. That is, the peripheral area PA may be a non-display area, in which an image is not displayed. A driving circuit configured to provide an electrical signal to the pixel PX or a power line configured to provide power to the pixel PX may be arranged in the peripheral area PA.

The display apparatus 1 may include a display panel 10, a cover window 20, and a bonding layer 30. The cover window 20 may be arranged on an upper surface (in a +z direction) of the display panel 10. Here, the “upper surface” of the display panel 10 may be defined as a surface in a direction in which the display panel 10 provides an image. According to an embodiment, the cover window 20 may be arranged to cover the upper surface of the display panel 10. The cover window 20 may protect the upper surface of the display panel 10. Also, the cover window 20 may form an exterior of the display apparatus 1, and thus, may include a flat surface and a curved surface corresponding to a shape of the display apparatus 1.

The cover window 20 may be bonded on the display panel 10 by the bonding layer 30. The bonding layer 30 may include, for example, a bonding member, such as an optical clear adhesive (OCA) or a pressure sensitive adhesive (PSA).

The cover window 20 may have high transmittance to transmit light emitted from the display panel 10 and little thickness to minimize the weight of the display apparatus 1. Also, the cover window 20 may have great rigidity and hardness to protect the display panel 10 from external shocks. The cover window 20 may include a flexible window. The cover window 20 may protect the display panel 10 by being easily bent according to an external force without cracks, etc. being generated.

The cover window 20 may include glass, sapphire, or plastic. In an embodiment, for example, the cover window 20 may include ultra-thin glass (UTG®), the rigidity of which is increased by chemical enhancement or thermal enhancement, or may include colorless polyimide (CPI). The cover window 20 may have a structure in which a flexible polymer layer is arranged on a surface of a glass substrate or may have a structure including only a polymer layer. The image displayed by the display panel 10 may be provided to a user through the cover window 20 that is transparent. That is, it may be understood that the image provided by the display apparatus 1 may be realized by the display panel 10.

Although not shown, a protective film (not shown) may be arranged below the display panel 10 to face a lower surface (in a −z direction) of the display panel 10. The protective film may protect the display panel 10 during a manufacturing process of the display apparatus 1. In an embodiment, for example, the protective film may include at least one selected from polydimethylsiloxane, polyethylene terephthalate (PET), polyimide, polyethylene naphthalate, polyarylate, polycarbonate, polyether imide (PEI), and polyethersulfone.

A bonding member may be arranged between the protective film and the display panel 10. The protective film may be bonded to the display panel 10 by the bonding member. The bonding member may include at least one selected from an optical clear resin (OCR), an OCA, and a PSA.

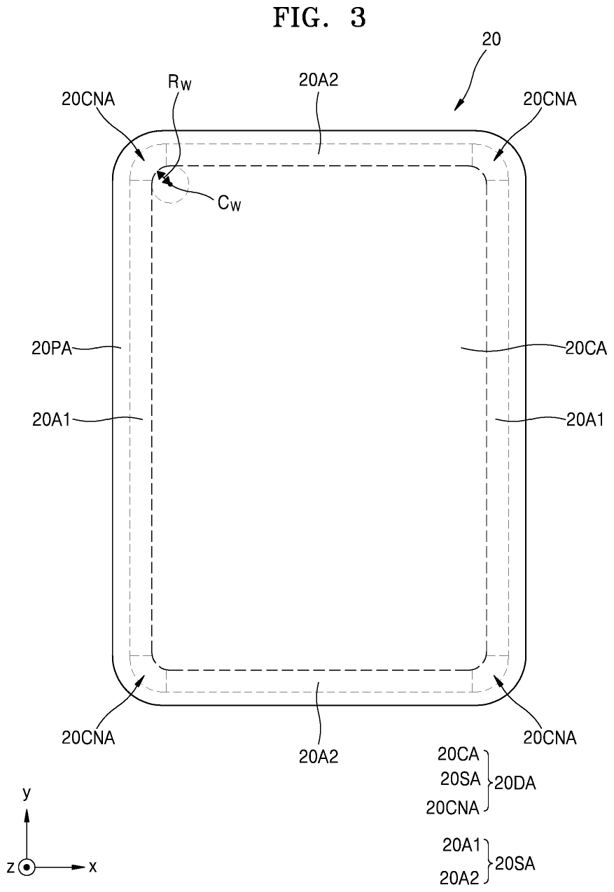

FIG. 3 is a schematic plan view of the cover window 20 of the display apparatus 1 according to an embodiment. The cover window 20 may include a window display area 20DA and a window peripheral area 20PA. The window display area 20DA may include a window central area 20CA, a window side area 20SA, and a window corner area 20CNA. The window side area 20SA may include a first window area 20A1 and a second window area 20A2.

As described above, the cover window 20 may include a flat surface and a curved surface corresponding to a shape of the display apparatus 1. In an embodiment, locations and shapes of the window display area 20DA and the window peripheral area may correspond to locations and shapes of the display area DA and the peripheral area PA, respectively. Locations and shapes of the window central area 20CA, the window side area 20SA, and the window corner area 20CNA may correspond to locations and shapes of the central area CA, the side area SA, and the corner area CNA, respectively. Locations and shapes of the first window area 20A1 and the second window area 20A2 may correspond to locations and shapes of the first area A1 and the second area A2, respectively.

In an embodiment, the window central area 20CA may be arranged at a central portion of the cover window 20. The first window area 20A1 may be connected to the window central area 20CA in the first direction (e.g., the x direction or the −x direction), and the second window area 20A2 may be connected to the window central area 20CA in the second direction (e.g., the y direction or the −y direction). The first window area and the second window area 20A2 may bend based on predetermined axes. In an embodiment, for example, the first window area 20A1 may bend based on an axis extending in the second direction (e.g., the y direction or the −y direction), and the second window area 20A2 may bend based on an axis extending in the first direction (e.g., the x direction or the −x direction). The window corner area 20CNA may be arranged to contact a corner of the window central area 20CA. Thus, the same any repetitive detailed description of the same or like features of the window display area 20DA and the window peripheral area 20PA as those of the display area DA and the peripheral area PA described above will be omitted.

The window display area 20DA may be an optically transparent area. Thus, the display panel 10 may display an image through the window central area 20CA, the window side area 20SA, and the window corner area 20CNA of the cover window 20 that are optically transparent. Similarly to the relationship between the display area DA and the peripheral area PA, the window display area 20DA may be surrounded by the window peripheral area 20PA, according to an embodiment. A light transmittance of the window peripheral area 20PA may be lower than a light transmittance of the window display area

Although not shown, a light-shielding layer (not shown) may be arranged in the window peripheral area 20PA. The light-shielding layer may include a light-shielding material. That is, the light-shielding layer may include a non-transparent material blocking light so that lines, circuits, etc. of the display panel 10 are not seen from the outside. The light-shielding material may include at least one selected from black dyes and black particles. In an embodiment, for example, the light-shielding material may include Cr, CrO_{X}, Cr/CrO_{X}, Cr/CrO_{X}/CrN_{Y}, resins (carbon pigments or RGB mixture pigments), graphite, or non-Cr-based pigments, lactam-based pigments, or perylene-based pigments. The light-shielding material may include black organic pigments, and the black organic pigments may include at least one selected from aniline black, lactam black, and perylene black.

The window central area 20CA of the cover window 20 may have a rectangular shape having a chamfered vertex. In such an embodiment, the window central area 20CA of the cover window 20 may have a rectangular shape with a round corner. Thus, a corner of the window central area 20CA of the cover window 20 may have a radius of curvature R_{W}. The radius of curvature R_{W} may be a distance from a center C_{W} of a circle to the round corner.

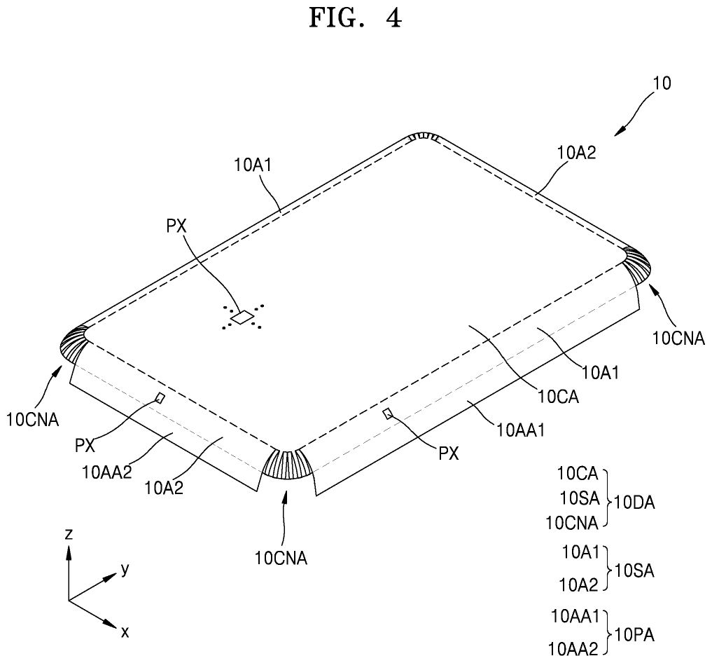

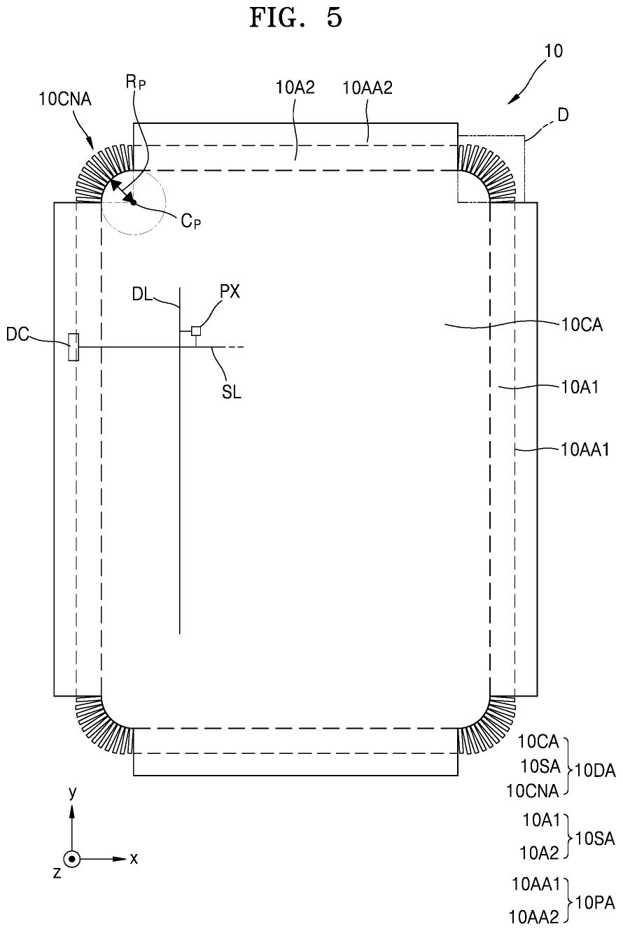

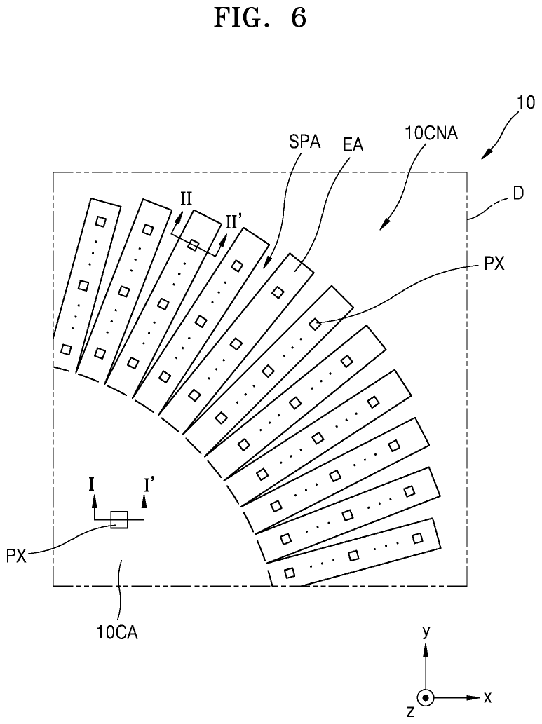

FIGS. 4 and 5 are schematic views of the display panel 10 of the display apparatus 1 according to an embodiment. In detail, FIG. 4 shows a schematic view of a state of the display panel 10, in which the display panel 10 is bent, and FIG. 5 shows a schematic view of the display panel 10 in a state, in which the display panel 10 is not bent and is flat. FIG. 6 is a schematic enlarged plan view of region D of the display panel 10 of FIG. 5.

The display panel 10 may include a panel display area 10DA and a panel peripheral area 10PA. The panel display area 10DA may include a panel central area 10CA, a panel side area 10SA, and a panel corner area 10CNA. The panel side area may include a first panel area 10A1 and a second panel area 10A2.

The panel central area 10CA may be arranged at a central portion of the display panel 10. The panel central area 10CA may have a rectangular shape having a chamfered vertex. In an embodiment, the panel central area 10CA may have a rectangular shape with a round corner. Thus, a corner of the panel central area 10CA may have a radius of curvature R_{P}. The radius of curvature R_{P} may be a distance from a center C_{P} of a circle to the round corner.

The panel side area 10SA may be arranged to be adjacent to a side of the panel central area 10CA. In an embodiment, the panel side area 10SA may include the first panel area 10A1 and the second panel area 10A2. The first panel area 10A1 may be adjacent to the panel central area 10CA in the first direction (e.g., the x direction or the −x direction). The first panel area 10A1 may extend in the second direction (e.g., the y direction or the −y direction). The second panel area 10A2 may be adjacent to the panel central area 10CA in the second direction. The second panel area 10A2 may extend in the first direction.

The panel corner area 10CNA may be arranged to be adjacent to the corner of the panel central area 10CA. As illustrated in FIG. 6, the panel corner area 10CNA may include an extension area EA. The extension area EA may extend in a direction away from the panel central area 10CA. The display panel 10 may include a plurality of extension areas EA. Each of the plurality of extension areas EA may extend in a direction away from the panel central area 10CA. In an embodiment, for example, the plurality of extension areas EA may extend in a direction crossing the first direction (e.g., the x direction or the −x direction) and the second direction (e.g., the y direction or the −y direction).

In an embodiment, as shown in FIG. 6, a spaced area SPA may be defined between an adjacent pair of the plurality of extension areas EA. The spaced area SPA may be an area, in which components of the display panel 10 are not arranged. When the panel corner area 10CNA bends, the compressive strain occurring in the panel corner area 10CNA may be greater than the tensile strain occurring in the panel corner area 10CNA. However, the spaced area SPA may be defined between the adjacent extension areas EA, and thus, the display panel 10 may bend in the panel corner area without being damaged.

The panel peripheral area 10PA may be arranged outside the panel display area 10DA. In an embodiment, the panel peripheral area 10PA may include a first panel adjacent area 10AA1 and a second panel adjacent area 10AA2. The first panel adjacent area 10AA1 may be arranged outside the first panel area 10A1. That is, the first panel area 10A1 may be arranged between the first panel adjacent area 10AA1 and the panel central area 10CA. Accordingly, the first panel adjacent area 10AA1 may be arranged in the first direction from the first panel area 10A1 and may extend in the second direction like the first panel area 10A1. The first panel adjacent area 10AA1 may be provided in plural, and the first panel areas 10A1 and the panel central area 10CA may be arranged between the plurality of first panel adjacent areas 10AA1. A driving circuit DC and/or a power line may be arranged in the first panel adjacent area 10AA1.

The second panel adjacent area 10AA2 may be arranged outside the second panel area 10A2. That is, the second panel area 10A2 may be arranged between the second panel adjacent area 10AA2 and the panel central area 10CA. Accordingly, the second panel adjacent area 10AA2 may be arranged in the second direction from the second panel area 10A2, and the second panel adjacent area 10AA2 may extend in the first direction like the second panel area 10A2. The second panel adjacent area 10AA2 may be provided in plural, and the second panel areas 10A2 and the panel central area 10CA may be arranged between the plurality of second panel adjacent areas 10AA2.

The display panel 10 may further include a bending area and a pad area. Although not shown, the bending area (not shown) may be arranged outside at least one selected from the second panel adjacent areas 10AA2. That is, the at least one selected from the second panel adjacent areas 10AA2 may be arranged between the bending area and the second panel area 10A2. Also, the pad area (not shown) may be arranged outside the bending area. That is, the bending area may be arranged between the at least one of the second panel adjacent areas 10AA2 and the pad area. The display panel 10 may bend in the bending area. In such an embodiment, the pad area may be arranged to overlap another portion of the display panel 10. Accordingly, an area of the panel peripheral area 10PA, which is seen by a user, may be minimized. A pad (not shown) may be arranged in the pad area. The display panel 10 may receive an electrical signal and/or a power voltage through the pad.

FIG. 5 illustrates an embodiment of the display panel 10 in the state, in which the display panel 10 is not bent and is flat. However, as described above, the display panel 10 may bend in a portion thereof. That is, as illustrated in FIG. 4, the panel side area 10SA, the panel corner area 10CNA, and the panel peripheral area 10PA may bend. In such an embodiment, the panel side area 10SA, the panel corner area 10CNA, and the panel peripheral area 10PA may bend based on predetermined axes. The panel side area 10SA and the panel peripheral area 10PA may be arranged on a side surface of the display panel 10, and the panel corner area 10CNA may be arranged at a corner of the display panel 10. The panel central area 10CA may be flat and may be arranged on an upper surface (in the +z direction) of the display panel 10.

In an embodiment, the first panel area 10A1 may bend based on the axis extending in the second direction to bend on the cross-section (e.g., the z-x cross-section) in the first direction and not to bend on the cross-section (e.g., the y-z cross-section) in the second direction. The second panel area 10A2 may bend based on the axis extending in the first direction to bend on the cross-section (e.g., the y-z cross-section) in the second direction and not to bend on the cross-section (e.g., the z-x cross-section) in the first direction. At least a portion of the panel corner area 10CNA may bend on both the cross-section (e.g., the z-x cross-section) in the first direction and the cross-section (e.g., the y-z cross-section) in the second direction. Accordingly, the at least the portion of the panel corner area 10CNA may be a multi-curved area in which a plurality of curvatures in a plurality of directions overlap one another.

When the panel corner area 10CNA bends as described above, the compressive strain occurring in the panel corner area 10CNA may be greater than the tensile strain occurring in the panel corner area 10CNA. Thus, it may be desired to apply a contractible structure of a substrate 100 to at least a portion of the panel corner area 10CNA. Accordingly, a structure of the display panel 10 in the panel corner area 10CNA may be different from a structure of the display panel 10 in the central panel area 10CA. That is, as described above, the panel corner area 10CNA may include the extension areas EA, and the spaced area SPA may be defined between the adjacent extension areas EA.

In an embodiment, as illustrated in FIGS. 4 to 6, the plurality of pixels PX may be arranged in the panel central area 10CA, the panel side area 10SA, and the panel corner area 10CNA. Thus, the display panel 10 may display an image in the panel central area 10CA, the panel side area 10SA, and the panel corner area 10CNA. In each of the plurality of extension areas EA, the plurality of pixels PX may be arranged in an extension direction of the extension area EA.

The pixel PX may include a display element. The display element may include an organic light-emitting diode including an organic emission layer. Alternatively, the display element may include a light-emitting diode including an inorganic emission layer. A size of the light-emitting diode may be micro-scale or nano-scale. In an embodiment, for example, the light-emitting diode may include a micro-light-emitting diode. Alternatively, the light-emitting diode may include a nanorod-light-emitting diode. The nanorod-light-emitting diode may include GaN. In an embodiment, a color conversion layer may be arranged on the display element. In such an embodiment, the color conversion layer may include quantum dots. Alternatively, the display element may include a quantum dot light-emitting diode including a quantum dot emission layer. Hereinafter, embodiments in which the display element includes an organic light-emitting diode is described, for convenience.

The pixel PX may include a plurality of sub-pixels, and each of the plurality of sub-pixels may emit a predetermined color of light by using the display element. The sub-pixel denotes a smallest unit for realizing an image and corresponds to an emission area. In an embodiment where an organic light-emitting diode is used as the display element, an emission area may be defined by an opening of a pixel-defining layer, which will be described below.

A driving circuit DC may be configured to provide a signal to the pixels PX. In an embodiment, for example, the driving circuit DC may include a scan driving circuit configured to provide, through a scan line SL, a scan signal to pixel circuits electrically connected to the sub-pixels included in the pixel PX. Alternatively, the driving circuit DC may include an emission control driving circuit configured to provide, through an emission control line (not shown), an emission control signal to the pixel circuits electrically connected to the sub-pixels. Alternatively, the driving circuit DC may include a data driving circuit configured to provide, through a data line DL, a data signal to the pixel circuits electrically connected to the sub-pixels. Although not shown, the data driving circuit may be arranged in the second panel adjacent area 10AA2 or the pad area. Alternatively, the data driving circuit may be arranged on a display circuit board connected to the display panel 10 through a pad.

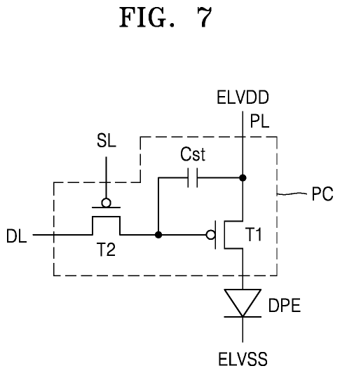

FIG. 7 is an equivalent circuit diagram of an embodiment of a pixel circuit PC included in the display apparatus 1 of FIG. 1. In detail, FIG. 7 is the equivalent circuit diagram of the pixel circuit PC electrically connected to an organic light-emitting diode, which is a display element DPE included in a sub-pixel included in the display apparatus 1 of FIG. 1. In an embodiment, the pixel circuit PC electrically connected to one sub-pixel may include a driving thin-film transistor T1, a switching thin-film transistor T2, and a storage capacitor Cst. According to an embodiment, the display element DPE may emit red, green, or blue light or red, green, blue, or white light.

The switching thin-film transistor T2 may be connected to the scan line SL and the data line DL and may be configured to transmit a data signal or a data voltage input through the data line DL, to the driving thin-film transistor T1, in response to a scan signal or a switching voltage input through the scan line SL.

The storage capacitor Cst may be connected to the switching thin-film transistor T2 and a driving voltage line PL and may be configured to store a voltage corresponding to a difference between a voltage received from the switching thin-film transistor T2 and a first power voltage ELVDD supplied to the driving voltage line PL.

The driving thin-film transistor T1 may be connected to the driving voltage line PL and the storage capacitor Cst and may be configured to control a driving current flowing from the driving voltage line PL through the organic light-emitting diode according to a value of the voltage stored in the storage capacitor Cst. The display element DPE may emit light having a certain brightness corresponding to the driving current. An opposite electrode of the display element DPE may receive a second power voltage ELVSS.

FIG. 7 illustrates an embodiment where the pixel circuit PC includes two thin-film transistors and one storage capacitor. However, the pixel circuit PC may include more thin-film transistors than the thin-film transistors illustrated in FIG. 7.

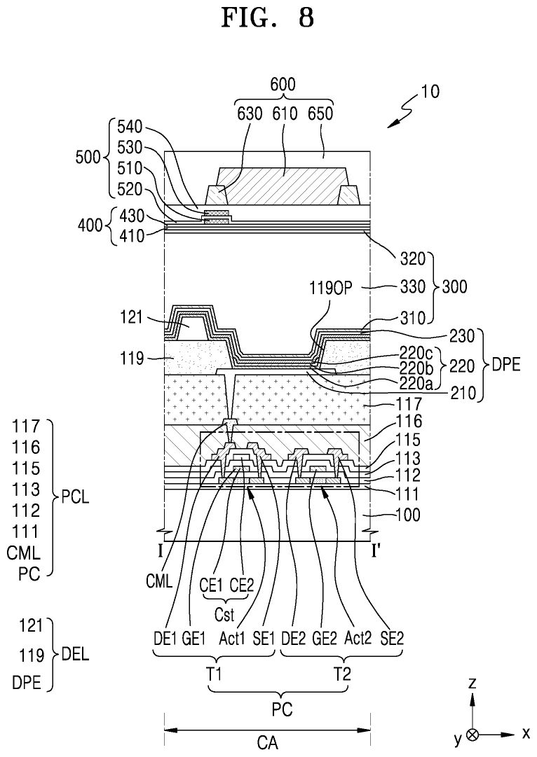

FIG. 8 is a schematic cross-sectional view of the display panel 10 of FIG. 6, taken along line I-I′. In an embodiment, as illustrated in FIG. 8, the display panel 10 included in the display apparatus 1 may include the substrate 100, a pixel circuit layer PCL, a display element layer DEL, an encapsulation layer 300, a protective layer 400, a touch sensor layer 500, and a reflection prevention layer 600.

The substrate 100 may include polymer resins, such as polyethersulfone, polyarylate, polyetherimide, polyethylene naphthalate, polyethylene terephthalate, polyphenylene sulfide, polyimide, polycarbonate, cellulose tri acetate, or cellulose acetate propionate. Alternatively, the substrate 100 may include two layers including the polymer resins and a barrier layer arranged between the two layers. In such an embodiment, the barrier layer may include inorganic materials, such as silicon nitride (SiN_{X}), silicon oxide (SiO_{X}), and/or silicon oxynitride (SiO_{X}N_{Y}). Alternatively, the substrate 100 may also include glass or metal.

The pixel circuit layer PCL may be arranged on the substrate 100. The pixel circuit layer PCL may include the pixel circuit PC, a buffer layer 111, a first gate insulating layer 112, a second gate insulating layer 113, an interlayer insulating layer 115, a first planarization layer 116, a second planarization layer 117, and a connection electrode CML. The pixel circuit PC may include at least one thin-film transistor. In an embodiment, the pixel circuit PC may include the driving thin-film transistor T1, the switching thin-film transistor T2, and the storage capacitor Cst.

The driving thin-film transistor T1 may include a first semiconductor layer Act1, a first gate electrode GE1, a first source electrode SE1, and a first drain electrode DE1. The pixel circuit layer PCL may further include the buffer layer 111, the first gate insulating layer 112, the second gate insulating layer 113, the interlayer insulating layer 115, the first planarization layer 116, and the second planarization layer 117 arranged above or/and below the components of the driving thin-film transistor T1.

The buffer layer 111 may reduce or block the penetration of impurities, moisture, or external materials from below the substrate 100 and may provide a planarized surface to the substrate 100. The buffer layer 111 may include an inorganic material, such as oxide or nitride, an organic material, or an organic and inorganic compound, and may have a single-layered structure or a multi-layered structure, each layer therein including the inorganic material or the organic material.

The first semiconductor layer Act1 may be arranged on the buffer layer 111. The first semiconductor layer Act1 may include polysilicon. Alternatively, the first semiconductor layer Act1 may include amorphous silicon, an oxide semiconductor, or an organic semiconductor. The first semiconductor layer Act1 may include a channel area, and a drain area and a source area arranged at opposing sides of the channel area, respectively.

The first gate electrode GE1 may overlap the channel area. The first gate electrode GE1 may include a low-resistance metal material. The first gate electrode GE1 may include a conductive material including Mo, Al, Cu, or Ti, etc. and may be defined by multi-layers or a single layer, each layer including at least one selected from the conductive materials described above.

The first gate insulating layer 112 may be arranged between the first semiconductor layer Act1 and the first gate electrode GE1. The first gate insulating layer 112 may include SiN_{X}, SiO_{X}, SiO_{X}N_{Y}, aluminum oxide (AL₂O₃), titanium oxide (TiO₂), tantalum oxide (Ta₂O₅), hafnium oxide (HfO₂) or zinc oxide (ZnO or ZnO₂).

The second gate insulating layer 113 may cover the first gate electrode GE1. The second gate insulating layer 113 may include SiN_{X}, SiO_{X}, SiO_{X}N_{Y}, Al₂O₃, TiO₂, Ta₂O₅, HfO₂ or ZnO or ZnO₂.

A second capacitor electrode CE2 of the storage capacitor Cst may be arranged above the second gate insulating layer 113. The second capacitor electrode CE2 may overlap the first gate electrode GE1 therebelow. Here, the first gate electrode GE1 of the driving thin-film transistor T1 and the second capacitor electrode CE2 overlapping each other with the second gate insulating layer 113 therebetween may be included in the storage capacitor Cst. That is, the first gate electrode GE1 of the driving thin-film transistor T1 may function as a first capacitor electrode CE1 of the storage capacitor Cst, and the storage capacitor Cst and the driving thin-film transistor T1 may overlap each other. The disclosure is not limited thereto. In an embodiment, for example, the storage capacitor Cst may not overlap the driving thin-film transistor T1. The second capacitor electrode CE2 may include Al, Pt, Pd, Ag, Mg, Au, Ni, Nd, Ir, Cr, Ca, Mo, Ti, W, and/or Cu and may be defined by a single layer or layers, each layer including at least one selected from the materials described above.

The interlayer insulating layer 115 may cover the second capacitor electrode CE2. The interlayer insulating layer 115 may include SiN_{X}, SiO_{X}, SiO_{X}N_{Y}, Al₂O₃, TiO₂, Ta₂O₅, HfO₂ or ZnO or ZnO₂.

Each of the first drain electrode DE1 and the first source electrode SE1 may be arranged on the interlayer insulating layer 115. The first drain electrode DE1 and the first source electrode SE1 may include a highly conductive material. The first drain electrode DE1 and the first source electrode SE1 may include a conductive material including Mo, Al, Cu, or Ti, etc. and may be defined by multi-layers or a single layer, each layer including at least one selected from the materials described above. In an embodiment, for example, the first drain electrode DE1 and the first source electrode SE1 may have a multi-layered structure of Ti/Al/Ti.

The switching thin-film transistor T2 may include a second semiconductor layer Act2, a second gate electrode GE2, a second drain electrode DE2, and a second source electrode SE2. The second semiconductor layer Act2, the second gate electrode GE2, the second drain electrode DE2, and the second source electrode SE2 may be substantially the same as the first semiconductor layer Act1, the first gate electrode GE1, the first drain electrode DE1, and the first source electrode SE1, respectively, and thus, any repetitive detailed descriptions thereof will be omitted.

The pixel circuit layer PCL may further include the driving circuit DC, and the driving circuit DC may be arranged in the panel central area 10CA. The driving circuit DC may include at least one thin-film transistor and may be connected to the scan line SL. Similarly to the switching thin-film transistor T2, the thin-film transistor included in the driving circuit DC may include a driving circuit-semiconductor layer, a driving circuit-gate electrode, a driving circuit-source electrode, and a driving circuit-drain electrode.

The first planarization layer 116 may cover the first drain electrode DE1 and the first source electrode SE1. The first planarization layer 116 may approximately have a flat upper surface. The first planarization layer 116 may include an organic material. In an embodiment, for example, the first planarization layer 116 may include a general-purpose polymer, such as benzocyclobutene (BCB), polyimide, hexamethyldisiloxane (HMDSO), polymethylmethacrylate (PMMA), or polystyrene (PS), a polymer derivate having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof. Alternatively, the first planarization layer 116 may include an inorganic material. In such an embodiment, the first planarization layer 116 may include SiN_{X}, SiO_{X}, SiO_{X}N_{Y}, Al₂O₃, TiO₂, Ta₂O₅, HfO₂ or ZnO or ZnO₂. In an embodiment where the first planarization layer 116 includes an inorganic material, chemical planarization polishing may be performed selectively. Alternatively, the first planarization layer 116 may include both an organic material and an inorganic material.

The pixel circuit layer PCL may further include the connection electrode CML, and the connection electrode CML may be arranged on the first planarization layer 116. Here, the connection electrode CML may be connected to the first drain electrode DE1 or the first source electrode SE1 through a contact hole defined in the first planarization layer 116. The connection electrode CML may include a highly conductive material. The connection electrode CML may include a conductive material including Mo, Al, Cu, or Ti, etc. and may be defined by multi-layers or a single layer, each layer including at least one selected from the conductive materials described above. In an embodiment, for example, the connection electrode CML may have a multi-layered structure of Ti/Al/Ti.

The second planarization layer 117 may cover the connection electrode CML. The second planarization layer 117 may approximately have a flat upper surface. The second planarization layer 117 may include an organic material. In an embodiment, for example, the second planarization layer 117 may include a general-purpose polymer, such as BCB, polyimide, HMDSO, PMMA, or PS, a polymer derivate having a phenol-based group, an acryl-based polymer, an imide-based polymer, an aryl ether -based polymer, an amide-based polymer, a fluorine-based polymer, a p-xylene-based polymer, a vinyl alcohol-based polymer, or a blend thereof. Alternatively, the second planarization layer 117 may include an inorganic material. In such an embodiment, the second planarization layer 117 may include SiN_{X}, SiO_{X}, SiO_{X}N_{Y}, Al₂O₃, TiO₂, Ta₂O₅, HfO₂or ZnO or ZnO₂. In an embodiment where the second planarization layer 117 includes an inorganic material, chemical planarization polishing may be performed selectively. Alternatively, the second planarization layer 117 may include both an organic material and an inorganic material.

The display element layer DEL may be arranged on the pixel circuit layer PCL. The display element layer DEL may include the display element DPE, a pixel-defining layer 119 and a spacer 121. An organic light-emitting diode, which is the display element DPE, may include a pixel electrode 210, the opposite electrode 230, and an intermediate layer 220 arranged between the pixel electrode 210 and the opposite electrode 230 and including an emission layer.

The pixel electrode 210 may be arranged on the second planarization layer 117 having the flat upper surface. The pixel electrode 210 may be electrically connected to the connection electrode CML through a contact hole defined in the second planarization layer 117. Also, as illustrated in FIG. 8, in the panel central area 10CA, the organic light-emitting diode, which is the display element DPE, may be arranged to overlap the pixel circuit PC electrically connected thereto.

The pixel electrode 210 may include a (semi-) transmissive electrode or a reflection electrode. According to some embodiments, the pixel electrode 210 may include a reflective layer including Ag, Mg, Al, Pt, Pd, Au, Ni, Nd, Ir, Cr, or a compound thereof, and a transparent or semi-transparent electrode layer on the reflective layer. The transparent or semi-transparent electrode layer may include at least one selected from indium tin oxide (ITO), indium zinc oxide (IZO), ZnO or ZnO₂, In₂O₃, indium gallium oxide (IGO), and aluminum zinc oxide (AZO). According to some embodiments, the pixel electrode 210 may have a structure in which ITO/Ag/ITO layers are stacked.

The pixel-defining layer 119 may be arranged on the second planarization layer 117, and an opening 119OP exposing a central portion of the pixel electrode 210 may be defined through the pixel-defining layer 119 to define an emission area of a pixel. Also, the pixel-defining layer 119 may increase a distance between edges of the pixel electrode 210 and the opposite electrode 230 on the pixel electrode 210 to prevent arcs, etc. from occurring at the edges of the pixel electrode 210. The pixel-defining layer 119 may be formed by using a spin coating method, etc. by using an organic insulating material, such as polyimide, polyamide, acryl resins, BCB, HMDSO or phenol resins, etc.

The intermediate layer 220 may be arranged on the pixel-defining layer 119. The intermediate layer 220 may include an emission layer 220b arranged in the opening 119OP of the pixel-defining layer 119 and overlapping the pixel electrode 210. The intermediate layer 220 may further include at least one selected from a first functional layer 220a arranged between the pixel electrode 210 and the emission layer 220b and a second functional layer 220c arranged on the emission layer 220b. The first functional layer 220a may include, for example, a hole transport layer (HTL), or an HTL and a hole injection layer (HIL). The second functional layer 220c may include an electron transport layer (ETL) and/or an electron injection layer (EIL). The first functional layer 220a and/or the second functional layer 220c may be commonly provided or integrally formed as a single unitary and indivisible body to correspond to the plurality of pixel electrodes 210.

The opposite electrode 230 may include a transmissive electrode or a reflection electrode. According to some embodiments, the opposite electrode 230 may include a transparent or semi-transparent electrode and may include a metal thin-film having a low work function, such as Li, Ca, LiF, Al, Ag, Mg, or a compound thereof. Also, in addition to the metal thin-film, the opposite electrode 230 may further include a transparent conductive oxide (TCO) layer, such as ITO, IZO, ZnO, or In₂O₃. The opposite electrode 230 may be commonly provided or integrally formed as a single unitary and indivisible body to correspond to the plurality of pixel electrodes 210.

The spacer 121 may be arranged on the pixel-defining layer 119. The spacer 121 may be provided to prevent damage to the substrate 100 and/or the layers on the substrate 100, according to a method of manufacturing a display apparatus. According to an embodiment of a method of manufacturing the display panel 10, a mask sheet may be used. Here, the mask sheet may be introduced into the opening 119OP of the pixel-defining layer 119 or may adhere to the pixel-defining layer 119. The spacer 121 may prevent or reduce damage or fractures in the substrate 100 and one or more of the layers, the damage or fractures being caused by the mask sheet, when a deposition material is deposited on the substrate 100.

The spacer 121 may include an organic material, such as polyimide. Alternatively, the spacer 121 may include an inorganic insulating material, such as SiN_{X}, SiO_{X}, or SiO_{X}N_{Y}, or an organic insulating material and an inorganic insulating material. The spacer 121 may include a different material from the pixel-defining layer 119. Alternatively, the spacer 121 may include a same material as the pixel-defining layer 119, and in such an embodiment, the pixel-defining layer 119 and the spacer 121 may be formed together by a mask process using a halftone mask, etc.

The encapsulation layer 300 including a first inorganic encapsulation layer 310, a second inorganic encapsulation layer 320, and an organic encapsulation layer 330 therebetween may be arranged on the opposite electrode 230.

The first inorganic encapsulation layer 310 and the second inorganic encapsulation layer 320 may include SiN_{X}, SiO_{X}, SiO_{X}N_{Y}, Al₂O₃, TiO₂, Ta₂O₅, HfO₂or ZnO or ZnO₂. The organic encapsulation layer 330 may include polyethylene terephthalate, polyethylene naphthalate, polycarbonate, polyimide, polyethylene sulfonate, polyoxymethylene, polyarylate, HMDSO, acryl-based resins (for example, polymethylmethacrylate, polyacryl acid, etc.), or a certain combination thereof.

The protective layer 400 may be arranged on the encapsulation layer 300. The protective layer 400 may protect the encapsulation layer 300. In an embodiment, for example, the protective layer 400 may prevent or reduce cracks occurring in at least one selected from the first inorganic encapsulation layer 310 and/or the second inorganic encapsulation layer 320. A second inorganic protective layer 430 may be arranged on a first inorganic protective layer 410.

The first inorganic protective layer 410 and the second inorganic protective layer 430 may include SiN_{X}, SiO_{X}, SiO_{X}N_{Y}, Al₂O₃, TiO₂, Ta₂O₅, HfO₂or ZnO or ZnO₂.

The touch sensor layer 500 may be arranged on the protective layer 400. The touch sensor layer 500 may obtain coordinate information according to an external input, for example, a touch event. The touch sensor layer 500 may include a first touch conductive layer 510, a first touch insulating layer 520, a second touch conductive layer 530, and a second touch insulating layer 540.

The first touch conductive layer 510 may be arranged on the second inorganic protective layer 430. The first touch conductive layer 510 may include a conductive material. In an embodiment, the first touch conductive layer 510 may include at least one selected from Mo, Al, Cu, and Ti. In an embodiment, for example, the first touch conductive layer 510 may have a multi-layered structure of Ti/Al/Ti, in which a Ti layer, an Al layer, and a Ti layer are sequentially stacked.

The first touch insulating layer 520 may be arranged on the first touch conductive layer 510. The first touch insulating layer 520 may include an inorganic material. In an embodiment, for example, the first touch insulating layer 520 may include at least one inorganic material selected from Al₂O₃, TiO₂, Ta₂O₅, HfO₂, ZnO, SiN_{X}, SiO_{X}, and SiO_{X}N_{Y}.

The second touch conductive layer 530 may be arranged on the first touch insulating layer 520. A contact hole may be defined through the first touch insulating layer 520, and the second touch conductive layer 530 may be connected to the first touch conductive layer 510 through the contact hole. The second touch conductive layer 530 may include a conductive material. In an embodiment, the second touch conductive layer 530 may include at least one selected from Mo, Al, Cu, and Ti. In an embodiment, for example, the second touch conductive layer 530 may have a multi-layered structure of Ti/Al/Ti, in which a Ti layer, an Al layer, and a Ti layer are sequentially stacked.

The second touch insulating layer 540 may be arranged on the second touch conductive layer 530. An upper surface of the second touch insulating layer 540 may be flat. The second touch insulating layer 540 may include an organic material. In an embodiment, the second touch insulating layer 540 may include a polymer-based material. The polymer-based material described above may be transparent. In an embodiment, for example, the second touch insulating layer 540 may include silicon-based resins, acryl-based resins, epoxy-based resins, polyimide or polyethylene, etc. The second touch insulating layer 540 may include an inorganic material.

The reflection prevention layer 600 may be arranged on the touch sensor layer 500. The reflection prevention layer 600 may reduce the reflectivity of light incident from the outside toward the display panel 10. The reflection prevention layer 600 may increase the color purity of light emitted from the display panel 10. The reflection prevention layer 600 may include a color filter 610, a black matrix 630, and a planarization layer 650. The color filter 610 may overlap the organic light-emitting diode, which is the display element DPE. The color filter 610 may be arranged by considering the color of light emitted from the organic light-emitting diode. The color filter 610 may include a red, green, or blue pigment or dye. Alternatively, the color filter 610 may further include quantum dots, in addition to the pigment or the dye described above. Alternatively, the color filter 610 may not include the pigment or the dye described above and may include scattered particles, such as oxide titanium.

The black matrix 630 may be arranged to be adjacent to the color filter 610 and may overlap at least one selected from the first touch conductive layer 510 and the second touch conductive layer 530. The black matrix 630 may at least partially absorb external light or internal reflection light. The black matrix 630 may include black pigments.

The planarization layer 650 may be arranged on the color filter 610 and the black matrix 630. An upper surface of the planarization layer 650 may be flat. The planarization layer 650 may include an organic material. In an embodiment, the planarization layer 650 may include a transparent polymer-based material. IN an embodiment, for example, the planarization layer 650 may include silicon-based resins, acryl-based resins, epoxy-based resins, polyimide, or polyethylene, etc.

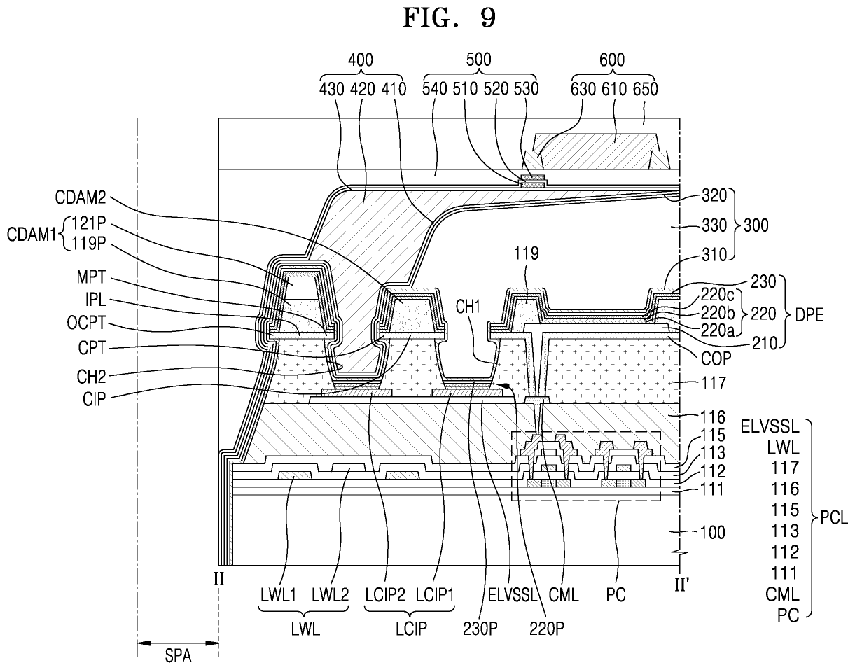

In FIG. 8, the pixel PX arranged in the panel central area 10CA of FIG. 6 is shown. Hereinafter, by referring to FIG. 9, which is a schematic cross-sectional view of the display panel 10 of FIG. 6, taken along line II-II′, a structure of a portion of the extension area EA around the spaced area SPA and the pixel PX arranged in the extension area EA will be described. Reference numerals indicated in FIG. 8 that are the same as reference numerals of FIG. 9 denote the same members as members illustrated in FIG. 9 or members corresponding to the members illustrated in FIG. 9, and thus, any repetitive detailed descriptions thereof will be omitted for convenience of description.

As illustrated in FIG. 9, the pixel circuit layer PCL may include the pixel circuit PC, the buffer layer 111, the first gate insulating layer 112, the second gate insulating layer 113, the interlayer insulating layer 115, the first planarization layer 116, the second planarization layer 117, and the connection electrode CML. The pixel circuit layer PCL may further include a lower line LWL and an electrode power supply line ELVSSL.

The lower line LWL may be configured to transmit a power voltage and/or an electrical signal to a pixel arranged in the panel corner area 10CNA. The lower line LWL may include a first lower line LWL1 and a second lower line LWL2. The first lower line LWL1 may be arranged between the first gate insulating layer 112 and the second gate insulating layer 113, and the second lower line LWL2 may be arranged between the second gate insulating layer 113 and the interlayer insulating layer 115.

The electrode power supply line ELVSSL may be arranged on the first planarization layer 116 like the connection electrode CML and may include a same material as the connection electrode CML and may be formed with the connection electrode CML in a same process. The electrode power supply line ELVSSL may be electrically connected to the opposite electrode 230 included in the organic light-emitting diode, which is the display element DPE, and may be configured to apply an electrical signal to the opposite electrode 230.

The second planarization layer 117 may cover the electrode power supply line ELVSSL and the connection electrode CML. As described above with reference to FIG. 7, a first corner hole CH1 and a second corner hole CH2 may be defined in the second planarization layer 117. A contact hole, through which the pixel electrode 210 on the second planarization layer 117 may be connected to the connection electrode CML, may be defined through the second planarization layer 117. The first corner hole CH1, the second corner hole CH2, and the contact hole may be simultaneously formed as one another.

The first corner hole CH1 and the second corner hole CH2 may overlap the electrode power supply line ELVSSL, and a lower corner inorganic pattern LCIP arranged on the electrode power supply line ELVSSL may prevent or minimize damage to the electrode power supply line ELVSSL in a process of forming the first corner hole CH1 and the second corner hole CH2. In an embodiment, the lower corner inorganic pattern LCIP may include a first lower corner inorganic pattern LCIP1 and a second lower corner inorganic pattern LCIP2, where the first lower corner inorganic pattern LCIP1 may overlap the first corner hole CH1, and the second lower corner inorganic pattern LCIP2 may overlap the second corner hole CH2. In such an embodiment, the electrode power supply line ELVSSL may not be exposed or may be minimally exposed in the process of forming the first corner hole CH1 and the second corner hole CH2, and thus, damage to the electrode power supply line ELVSSL may be prevented or minimized. The lower corner inorganic pattern LCIP may include SiN_{X}, SiO_{X}, SiO_{X}N_{Y}, Al₂O₃, TiO₂, Ta₂O₅, HfO₂ or ZnO or ZnO₂.

An overlapping inorganic pattern COP, a corner inorganic pattern CIP, and an inorganic pattern line IPL may be arranged on the second planarization layer 117. The overlapping inorganic pattern COP, the corner inorganic pattern CIP, and the inorganic pattern line IPL may include the same material as one another and may be simultaneously formed with one another. The overlapping inorganic pattern COP, the corner inorganic pattern CIP, and the inorganic pattern line IPL may include SiN_{X}, SiO_{X}, SiO_{X}N_{Y}, Al₂O₃, TiO₂, Ta₂O₅, HfO₂or ZnO or ZnO₂.

The overlapping inorganic pattern COP may be arranged on the second planarization layer 117 and may be arranged around the contact hole. In an embodiment, as illustrated in FIG. 9, the overlapping inorganic pattern COP may also be arranged on an inner surface of the contact hole. In such an embodiment, the pixel electrode 210 arranged on the second planarization layer 117 may be arranged on the overlapping inorganic pattern COP and may be connected to the connection electrode CML through the contact hole.

The corner inorganic pattern CIP may be spaced apart from the overlapping inorganic pattern COP by the first corner hole CH1 and may have a shape at least partially surrounding the overlapping inorganic pattern COP in a plan view. The inorganic pattern line IPL may be spaced apart from the corner inorganic pattern CIP by the second corner hole CH2 and may have a shape at least partially surrounding the corner inorganic pattern CIP in a plan view.

The corner inorganic pattern CIP may have a corner protrusion tip CPT protruding in a central direction of the first corner hole CH1 or the second corner hole CH2. FIG. 9 illustrates an embodiment where the corner inorganic pattern CIP protrudes in a central direction of each of the first corner hole CH1 and the second corner hole CH2. The inorganic pattern line IPL may have a middle protrusion tip MPT protruding in the central direction of the second corner hole CH2. Also, the inorganic pattern line IPL may have an outer corner protrusion tip OCPT protruding in a direction of the spaced area SPA. In an embodiment, as illustrated in FIG. 9, the overlapping inorganic pattern COP may also have a protrusion tip protruding in the central direction of the first corner hole CH1.

The pixel-defining layer 119 may cover an edge of the pixel electrode 210. Here, a first pattern 119P may be formed with the pixel-defining layer 119 in a same process by using a same material as the pixel-defining layer 119. The first pattern 119P may be arranged on the inorganic pattern line IPL. The first pattern 119P and the inorganic pattern line IPL may be included in a first corner dam CDAM1. In an embodiment, a second pattern 121P, which is arranged on the first pattern 119P, may be formed with the spacer 121 in a same process, which is arranged on the pixel-defining layer 119, by using a same material as the spacer 121. In such an embodiment, the first pattern 119P and the second pattern 121P may be included in the first corner dam CDAM1, together with the inorganic pattern line IPL. In addition, a second corner dam CDAM2 apart from the first corner dam CDAM1 and arranged on the corner inorganic pattern CIP may be formed with the pixel-defining layer 119 in a same process by using a same material as the pixel-defining layer 119.

Like the panel central area 10CA described above with reference to FIG. 8, the intermediate layer 220 may be arranged on the pixel-defining layer 119 also in the extension area EA. The intermediate layer 220 may include the emission layer 220b arranged in the opening of the pixel-defining layer 119 and overlapping the pixel electrode 210. The intermediate layer 220 may further include at least one selected from the first functional layer 220a arranged between the pixel electrode 210 and the emission layer 220b and the second functional layer 220c arranged on the emission layer 220b.

In an embodiment, as described above, the overlapping inorganic pattern COP may have the protrusion tip protruding in the central direction of the first corner hole CH1. Also, the corner inorganic pattern CIP may have the corner protrusion tip CPT protruding in the central direction of the first corner hole CH1. Accordingly, when the first functional layer 220a and the second functional layer 220c are formed, a functional layer pattern 220P spaced apart from the first function layer 220a and the second functional layer 220c by the protrusion tip of the overlapping inorganic pattern COP and the corner protrusion tip CPT of the corner inorganic pattern CIP and arranged in the first corner hole CH1 may be formed. Also, as described above, the inorganic pattern line IPL may have the middle protrusion tip MPT protruding in the central direction of the second corner hole CH2. Accordingly, when the first functional layer 220a and the second functional layer 220c are formed, the functional layer pattern 220P arranged in the second corner hole CH2 due to the corner protrusion tip CPT and the middle protrusion tip MPT may be formed.

The opposite electrode 230 may be disposed on the pixel-defining layer 119 and the intermediate layer 220 to correspond to the plurality of pixel electrodes 210. Thus, based on the same reason that the functional layer pattern 220P arranged in the first corner hole CH1 and the second corner hole CH2 may be formed, a common electrode pattern 230P arranged in the first corner hole CH1 and the second corner hole CH2 may be formed.

In an embodiment, the first inorganic encapsulation layer 310 included in the encapsulation layer 300 may be arranged on the opposite electrode 230 and may directly contact the protrusion tip of the overlapping inorganic pattern COP, the corner protrusion tip CPT of the corner inorganic pattern CIP, and the middle protrusion tip MPT of the inorganic pattern line IPL. In such an embodiment, the first inorganic encapsulation layer 310 may contact the common electrode pattern 230P in the first corner hole CH1 and the second corner hole CH2 and may cover inner surfaces of the first corner hole CH1 and the second corner hole CH2, as illustrated in FIG. 9. The organic encapsulation layer 330 included in the encapsulation layer 300 may be arranged on the first inorganic encapsulation layer 310 and may fill the first corner hole CH1 as illustrated in FIG. 9. The second corner dam CDAM2 may prevent a material for forming the organic encapsulation layer 330 from being discharged to the outside in the manufacturing process. The second inorganic encapsulation layer 320 included in the encapsulation layer 300 may be arranged on the organic encapsulation layer 330. The second inorganic encapsulation layer 320 may directly contact the first inorganic encapsulation layer 310 on the second corner dam CDAM2. In an embodiment, the second inorganic encapsulation layer 320 may also directly contact the first inorganic encapsulation layer 310 in the second corner hole CH2.

The protective layer 400 may include the first inorganic protective layer 410, the organic protective layer 420, and the second inorganic protective layer 430. The first inorganic protective layer 410 may be arranged on the encapsulation layer 300, and the organic protective layer 420 may be arranged on the first inorganic protective layer 410. Also, the second inorganic protective layer 430 may be arranged on the organic protective layer 420. The organic protective layer 420 may fill the second corner hole CH2. The second inorganic protective layer 430 may directly contact the first inorganic protective layer 410 on the first corner dam CDAM1. The first inorganic protective layer 410 and the second inorganic protective layer 430 may surround the corner protrusion tip CPT of the corner inorganic pattern CIP. Also, the first inorganic protective layer 410 and the second inorganic protective layer 430 may surround the outer corner protrusion tip OCPT of the inorganic pattern line IPL. In such an embodiment, damage to a display apparatus, caused by oxygen or water from the outside, may be effectively prevented, and the mechanical rigidity of the display apparatus may be increased, and thus, the display apparatus may be protected from damage due to external shock.

The touch sensor layer 500 may be arranged on the protective layer 400. The touch sensor layer 500 may include the first touch conductive layer 510, the first touch insulating layer 520, the second touch conductive layer 530, and the second touch insulating layer 540. According to an embodiment, the second touch insulating layer 540 may overlap the outer corner protrusion tip OCPT of the inorganic pattern line IPL.

Like the panel central area 10CA described above with reference to FIG. 8, the reflection prevention layer 600 may also be arranged on the touch sensor layer 500 in the extension area EA. The reflection prevention layer 600 may include, for example, the color filter 610, the black matrix 630, and the planarization layer 650. The color filter 610 may overlap the pixel electrode 210.

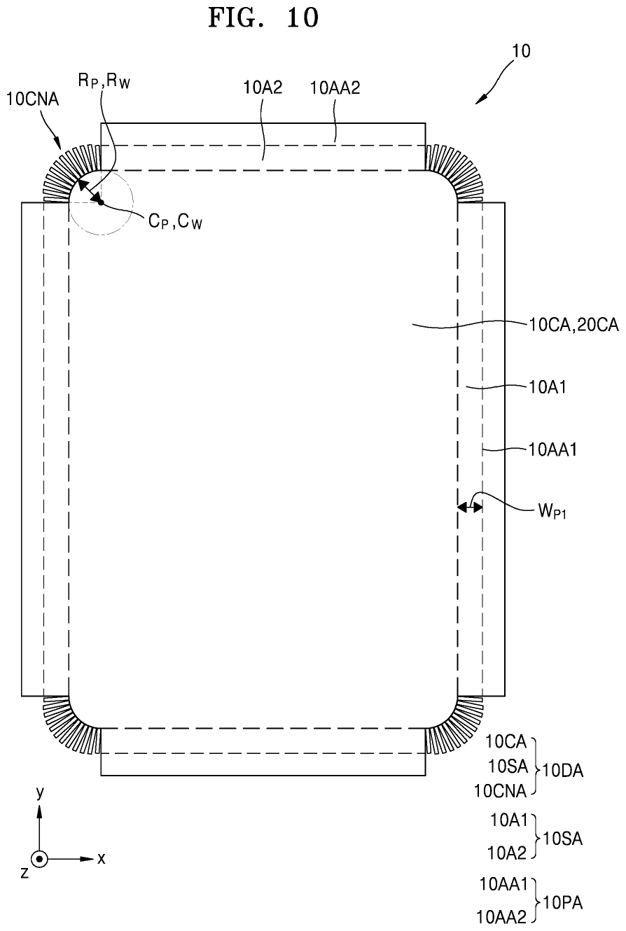

FIG. 10 is a schematic plan view of the display panel 10 of the display apparatus 1 according to an embodiment. In detail, FIG. 10 shows a schematic view of the display panel 10 in a state, in which the display panel 10 is not bent and is flat. FIG. 10 illustrates the window central area 20CA of the cover window 20 of the display apparatus 1 together, for convenience of description.

In an embodiment, as illustrated in FIG. 10, the display panel 10 may include the panel central area 10CA, the panel side area 10SA, the panel corner area 10CNA, and the panel peripheral area 10PA. As described above, the panel central area 10CA may have a rectangular shape having a chamfered vertex. In other words, the panel central area 10CA may have a rectangular shape with a round corner. Thus, the corner of the panel central area 10CA may have a radius of curvature R_{P}. The radius of curvature R_{P} may be a distance from a center C_{P} of a circle to the round corner.

The radius of curvature R_{P} of the corner of the panel central area 10CA may be the same as the radius of curvature R_{W} of the corner of the window central area 20CA of the cover window 20. That is, the distance from the center C_{W} of the circle to the round corner may be the same as the distance from the center C_{P} of the circle to the round corner.

In an embodiment, an area of the panel central area 10CA may be the same as an area of the window central area 20CA. That is, the panel central area 10CA and the window central area 20CA may completely overlap each other. Thus, the panel central area 10CA may overlap only the window central area 20CA that is flat. That is, the panel central area 10CA may be arranged below the window central area 20CA. The panel central area 10CA may not overlap areas of the cover window 20, the areas bending based on predetermined axes. In an embodiment, for example, the panel central area may not overlap the window side area 20SA and the window corner area 20CNA. That is, the panel central area 10CA may not be arranged below the window side area and may not be arranged below the window corner area 20CNA.

In such an embodiment, as described above with reference to FIGS. 3 and 4, the window side area 20SA, the window corner area 20CNA, and the window peripheral area may overlap the panel side area 10SA, the panel corner area 10CNA, and the panel peripheral area 10PA, respectively. That is, the panel side area 10SA may be arranged below the window side area 20SA, the panel corner area 10CNA may be arranged below the window corner area 20CNA, and the panel peripheral area 10PA may be arranged below the window peripheral area 20PA. In such an embodiment, the first panel area 10A1 may be arranged below the first window area 20A1, and the second panel area 10A2 may be arranged below the second window area 20A2.

As described above with reference to FIG. 2A, the first area A1 of the display apparatus 1 may bend based on the axis extending in the second direction (e.g., the y direction or the −y direction) and may have the first radius of curvature R1. The first radius of curvature R1 may be the same as a radius of curvature of a portion of the display panel 10, which is arranged below (or to overlap) the first window area 20A1 and bending based on the axis extending in the second direction (e.g., the y direction or the −y direction). In an embodiment, when the radius of curvature of the portion of the display panel 10, which is arranged below the first window area 20A1 and is bent based on the axis extending in the second direction (e.g., the y direction or the −y direction), is R_{B}, and a length of the portion of the display panel 10, which is arranged below the first window area 20A1, in a direction perpendicular to a portion of the display panel 10, which is arranged below the window central area 20CA, is Z₀, a first width W_{P1} of the portion of the display panel 10 in the first direction (e.g., a length along the curvature in the x direction or the −x direction), which is arranged below the first window area 20A1, may satisfy the following Equation 1.

$${W}_{P 1} = \frac{π {R}_{B}}{2} \times \frac{{cos}^{- 1} \frac{{R}_{B} - {Z}_{0}}{{R}_{B}}}{90} \qquad [ Equation 1 ]$$

As described above, the first panel area 10A1 may be arranged below the first window area 20A1 and may bend based on the axis extending in the second direction (e.g., they direction or the −y direction), and the panel central area 10CA may be arranged below the window central area 20CA. In other words, when the radius of curvature of the first panel area 10A1 is R_{B}, and a length of the first panel area 10A1 in the direction (e.g., a z-axis direction) perpendicular to the panel central area 10CA is Z₀, a width of the first panel area 10A1 in the first direction (e.g., a length along the curvature in the x direction or the −x direction) may be the same as the first width W_{P1}.

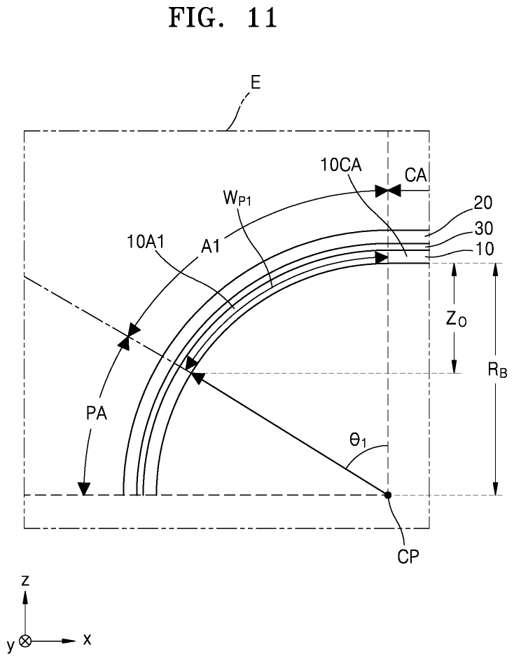

FIG. 11 is a view for describing the first width W_{P1} of the display panel 10 of the display apparatus 1 according to an embodiment. In detail, FIG. 11 is an enlarged schematic cross-sectional view of region E of the display apparatus 1 of FIG. 2A.

As illustrated in FIG. 11, the first panel area 10A1 bending based on the axis extending in the second direction (e.g., the y direction or the −y direction) may have an arc shape. An angle formed by the arc may be θ1, a radius of curvature of the arc may be R_{B}, and a circumference of the arc may be W_{P1}. Since the length of the first panel area 10A1 in the direction (e.g., the z-axis direction) perpendicular to the panel central area 10CA is Z₀, θ₁ may be cos⁻¹((R_{B}−Z₀)/R_{B}). When an angle formed by the arc is 90°, a circumference of the arc may be πR_{B}/2, and thus, when the angle formed by the arc is θ₁, the circumference of the arc may be (πR_{B}/2)×(θ₁/90). Thus, the circumference of the arc may be (πR_{B}/2)×((cos⁻¹((R_{B}−Z₀)/R_{B}))/90). Accordingly, the width of the first panel area 10A1 of the display apparatus 1 in the first direction (e.g., the x direction or the −x direction), according to an embodiment, may be the same as the first width W_{P1}, and the first width W_{P1} of the portion of the display panel 10 in the first direction (e.g., the x direction or the −x direction), which is arranged below the first window area 20A1, may satisfy Equation 1.

A radius of curvature of a portion of the display panel 10, which is arranged below the second window area 20A2, may be the same as R_{B}, and a length of the portion of the display panel 10, which is arranged below the second window area 20A2, in the direction (e.g., the z-axis direction) perpendicular to the portion of the display panel 10, which is arranged below the window central area 20CA, may be the same as Z₀. Accordingly, a width of the portion of the display panel 10 in the second direction (e.g., they direction or the −y direction), which is arranged below the second window area 20A2, may be the same as the first width W_{P1}. A width of the second panel area 10A2 in the second direction (e.g., the y direction or the −y direction) may be the same as the first width W_{P1}. The above description of the width of the first panel area 10A1 in the first direction (e.g., the x direction or the −x direction) may be likewise applied to the width of the second panel area 10A2 in the second direction (e.g., a length along the curvature in they direction or the −y direction), and thus, any repetitive detailed description thereof is omitted.

As described above, the display panel 10 may be arranged below the cover window 20. Accordingly, the display panel 10 may also be arranged below the window corner area 20CNA. If the first width W_{P1} does not satisfy Equation 1, the length of the display panel 10 in the direction (e.g., the z-axis direction) perpendicular to the panel central area 10CA may vary according to areas of the display panel 10.

For example, in a case where the window side area 20SA, the window corner area 20CNA, and the window peripheral area 20PA respectively overlap the panel side area 10SA, the panel corner area 10CNA, and the panel peripheral area 10PA, if the first width W_{P1} is less than that satisfying Equation 1, the length of the panel side area 10SA may be less than the length of the panel corner area 10CNA, with respect to the direction (e.g., the z-axis direction) perpendicular to the panel central area 10CA. In other words, with respect to the direction (e.g., the z-axis direction) perpendicular to the panel central area 10CA, a length of a portion of the display panel 10, which is arranged below the window side area 20SA, may be less than a length of a portion of the display panel 10, which is arranged below the window corner area 20CNA.

Accordingly, the display area DA of the display apparatus 1 may not have a smooth circumference. Thus, the display area DA of the display apparatus 1 may not have a proper shape in terms of design and may have a reduced aesthetic sense or appeal.

For example, in the case where the window side area 20SA, the window corner area 20CNA, and the window peripheral area 20PA respectively overlap the panel side area 10SA, the panel corner area 10CNA, and the panel peripheral area 10PA, if the first width W_{P1} is greater than that satisfying Equation 1, the length of the panel side area 10SA may be greater than the length of the panel corner area 10CNA, with respect to the direction (e.g., the z-axis direction) perpendicular to the panel central area 10CA. In other words, with respect to the direction (e.g., the z-axis direction) perpendicular to the panel central area 10CA, the length of the portion of the display panel 10, which is arranged below the window side area 20SA, may be greater than the length of the portion of the display panel 10, which is arranged below the window corner area 20CNA.

Thus, a portion of the display panel 10, in which the pixel PX is arranged, that is, a portion of the panel side area 10SA may overlap the window peripheral area 20PA. As described above, the light shielding layer may be arranged in the window peripheral area and thus, an image may not be displayed on the portion of the panel side area which is overlapping the window peripheral area 20PA. Thus, the efficiency of the display apparatus 1 may be reduced.

According to an embodiment of the display apparatus 1 according to the invention, the first width W_{P1} satisfies Equation 1, and thus, the length of the panel corner area and the length of the panel side area 10SA in the direction (e.g., the z-axis direction) perpendicular to the panel central area 10CA may be the same as each other. In such an embodiment, the length of the portion of the display panel 10, which is arranged below the window corner area 20CNA, and the length of the portion of the display panel 10, which is arranged below the window side area 20SA, in the direction (e.g., the z-axis direction) perpendicular to the panel central area 10CA, may be the same as each other. Accordingly, the display area DA of the display apparatus 1 may have a smooth circumference. Thus, the display area DA of the display apparatus 1 may have a proper shape in terms of design and may have an improved aesthetic sense or appeal. That is, a dead space of the display apparatus 1 may be reduced, and the display apparatus 1 may provide an improved aesthetic sense or appeal.

FIGS. 10 and 11 illustrate an embodiment where the radius of curvature R_{P} of the corner of the panel central area 10CA is the same as the radius of curvature R_{W} of the corner of the window central area 20CA. However, the disclosure is not limited thereto. In an alternative embodiment, for example, the radius of curvature R_{P} of the corner of the panel central area 10CA may be greater than the radius of curvature R_{W} of the corner of the window central area 20CA.

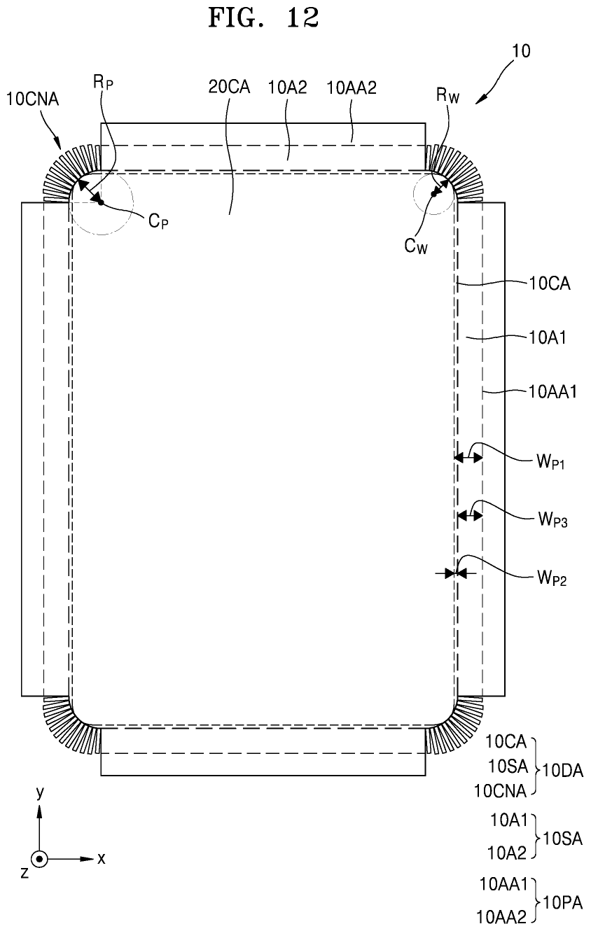

FIG. 12 is a schematic plan view of the display panel 10 of the display apparatus 1 according to an embodiment. In detail, FIG. 12 shows a schematic view of the display panel 10 in a state, in which the display panel 10 is not bent and is flat. FIG. 12 illustrates the window central area 20CA of the cover window 20 of the display apparatus 1 together, for convenience of description. The embodiment of the display apparatus 1 shown in FIG. 12 is substantially the same as the embodiment of the display apparatus 1 described above with reference to FIGS. 1 to 11, and thus, descriptions of the display apparatus 1 according to the present embodiment are given mainly based on differences from the display apparatus 1 described above with reference to FIGS. 1 to 11.

In an embodiment, as illustrated in FIG. 12, the display panel 10 may include the panel central area 10CA, the panel side area 10SA, the panel corner area 10CNA, and the panel peripheral area 10PA. The corner of the panel central area 10CA of the display apparatus 1 according to the embodiments described above with reference to FIG. 10, etc. may have the radius of curvature R_{P}. The radius of curvature R_{P} of the corner of the panel central area 10CA may be the same as the radius of curvature R_{W} of the corner of the window central area 20CA.

In an embodiment shown in FIG. 12, the corner of the panel central area 10CA of the display apparatus 1 may have the radius of curvature R_{P}. In such an embodiment, the radius of curvature R_{P} of the corner of the panel central area 10CA may be greater than the radius of curvature R_{W} of the corner of the window central area 20CA. That is, the radius of curvature R_{W} of the corner of the window central area 20CA may be less than the radius of curvature R_{P} of the corner of the panel central area 10CA.

In such an embodiment, an area of the panel central area 10CA may be greater than an area of the window central area 20CA. That is, a portion of the panel central area 10CA may be arranged below the window central area 20CA, and another portion of the panel central area 10CA may not be arranged below the window central area 20CA. The other portion of the panel central area 10CA may be arranged below the first window area 20A1 or the second window area 20A2. In such an embodiment, the first panel area 10A1 may be arranged below the first window area 20A1, the second panel area 10A2 may be arranged below the second window area 20A2, and the panel corner area 10CNA may be arranged below the window corner area 20CNA.

In such an embodiment, as illustrated in FIG. 12, the panel central area 10CA may protrude more in the first direction (e.g., the x direction or the −x direction) than the window central area 20CA, and the panel central area 10CA may protrude more in the second direction (e.g., the y direction or the −y direction) than the window central area 20CA. A protruding portion may have a second width W_{P2}. In such an embodiment, when the radius of curvature of the corner of the window central area 20CA of the cover window 20 is R_{W}, and the radius of curvature of the corner of the panel central area 10CA of the display panel 10 is R_{P}, the second width W_{P2} of the protruding portion of the panel central area 10CA of the display panel 10 of the display apparatus 1 may satisfy following Equation 2.

$${W}_{P 2} = {R}_{P} - {R}_{W} - \frac{{R}_{P} - {R}_{W}}{\sqrt{2}} = - ( 1 - \frac{1}{\sqrt{2}} ) {R}_{W} + ( 1 - \frac{1}{\sqrt{2}} ) {R}_{P} \qquad [ Equation 2 ]$$

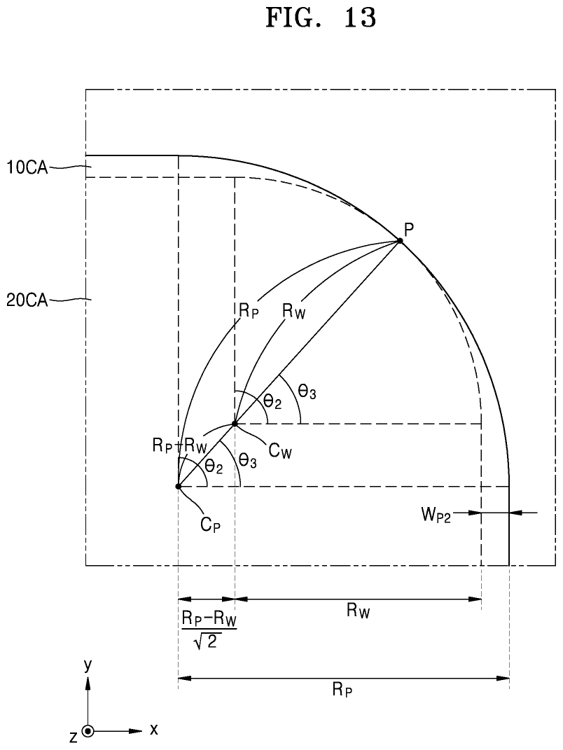

FIG. 13 is a view for describing the second width W_{P2} of the display panel 10 of the display apparatus 1 according to an embodiment. In detail, FIG. 13 shows a schematic view of the corner of the panel central area 10CA overlapping the window central area 20CA.

In an embodiment, as illustrated in FIG. 13, the corner of the window central area of the cover window 20 may have an arc shape having the radius of curvature of R_{W} and an angle of θ₁. The corner of the panel central area 10CA of the display panel may have an arc shape having the radius of curvature of R_{P} and an angle of θ₂. θ₂ may be 90°. Circumferences of the two arcs may contact each other at a point P. Lines connecting centers C_{W} and C_{P} of the arcs with the point P may bisect the two arcs. That is, the arcs may be bisected to have an angle of θ₃, and θ₃ may be 45°. Thus, a length between the centers C_{W} and C_{P} of the arcs in the first direction may be (R_{P}−R_{W})/\sqrt{2}. The panel central area 10CA may protrude more in the first direction (e.g., the x direction or the −x direction) than the window central area 20CA, by a length obtained by subtracting, from the radius of curvature R_{P}, the radius of curvature R_{W} and the length between the centers C_{W} and C_{P} of the arcs in the first direction. Accordingly, the panel central area may protrude more by R_{P}−R_{W}−(R_{P}−R_{W})/\sqrt{2} in the first direction (e.g., the x direction or the −x direction) than the window central area 20CA. Thus, in such an embodiment, the second width W_{P2} of the protruding portion of the panel central area 10CA of the display apparatus 1 may satisfy [Equation 2]. in such an embodiment, the panel central area 10CA may protrude more in the second direction (e.g., the y direction or the −y direction) than the window central area 20CA, and a width of a protruding portion thereof may be the same as the second width W_{P2}. The above description about the second width W_{P2} may be likewise applied to widths of protruding portions of similar kinds, and thus, any repetitive detailed description thereof is omitted.

In such an embodiment, the first panel area 10A1 may have a third width W_{P3} in the first direction (e.g., the x direction or the −x direction). In such an embodiment, the third width W_{P3} of the first panel area 10A1 of the display apparatus 1 may satisfy the following Equation 3.

W_{P3}=W_{P1}−W_{P2} [Equation 3]

When the radius of curvature R_{P} of the corner of the panel central area 10CA is greater than the radius of curvature R_{W} of the corner of the window central area 20CA, a portion of the panel central area 10CA, which is overlapping the window central area 20CA, may be arranged on an upper surface (in a +z direction) of the display panel 10, and a portion of the panel central area 10CA, which is not overlapping the window central area 20CA, may be arranged on a side surface or a corner of the display panel 10. In other words, a portion of the panel central area 10CA and the first panel area 10A1 may be arranged on the side surface of the display panel 10. Alternatively, a portion of the panel central area 10CA and the second panel area 10A2 may be arranged on the side surface of the display panel 10.

The portion of the panel central area 10CA, which is protruding more in the first direction (e.g., the x direction or the −x direction) than the window central area 20CA, may be arranged on the side surface of the display panel 10, and the width of the protruding portion of the panel central area 10CA may be the same as the second width W_{P2}. Thus, a width of the first panel area 10A1 in the first direction (e.g., the x direction or the −x direction), which is arranged on the side surface of the display panel 10, may be the same as W_{P1}−W_{P2}. In such an embodiment, the third width W_{P3} of the first panel area 10A1 of the display apparatus 1 may satisfy the Equation 3 described above. In such an embodiment, a width of the second panel area 10A2 in the second direction (e.g., the y direction or the −y direction) may be the same as the third width W_{P3}. The above description about the third width W_{P3} may be likewise applied to the width of the second panel area 10A2 in the second direction (e.g., they direction or the −y direction), and thus, any repetitive detailed description thereof is omitted.

Even when the radius of curvature R_{P} of the corner of the panel central area 10CA, as described above with reference to FIGS. 12 and 13, is greater than the radius of curvature R_{W} of the corner of the window central area 20CA, the width of the portion of the display panel 10 in the first direction (e.g., the x direction or the −x direction), which is arranged below the first window area 20A1, may be the same as the first width W_{P1}, when the second width W_{P2} and the third width W_{P3} satisfy the Equation 2 and the Equation 3, respectively. In such an embodiment, a width of the portion of the display panel 10 in the second direction (e.g., the y direction or the −y direction), which is arranged below the second window area 20A2, may be the same as the first width W_{P1}.

Thus, the effect generated when the first width W_{P1} of the display panel 10 of the display apparatus 1 satisfies the Equation 1, according to the embodiments described above with reference to FIGS. 10 and 11, etc., may also be obtained when the second width W_{P2} and the third width W_{P3} of the display panel 10 of the display apparatus 1 satisfy the Equation 2 and the Equation 3, respectively, in the embodiment described above with reference to FIGS. 12 and 13. Thus, the same description as described above is omitted.

Embodiments of the display apparatus 1 is described above. However, the disclosure is not limited thereto. It would be understood that a method of manufacturing the display apparatus 1 may also be included in the scope of the disclosure. Hereinafter, an embodiment of the method of manufacturing the display apparatus 1 will be described.

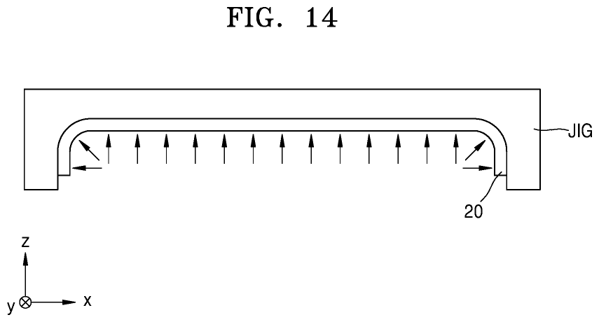

FIGS. 14 to 20C are views for describing a method of manufacturing the display apparatus 1, according to an embodiment. In detail, FIGS. 14 to 20C are schematic views for describing a process of manufacturing the display apparatus 1 including the display panel 10 of FIG. 10 or the display panel 10 of FIG. 12. The display apparatus 1 described above with reference to FIGS. 1 to 13 may be manufactured by the method of manufacturing the display apparatus 1. Hereinafter, any repetitive detailed description of features or elements that are the same as those described above with reference to FIGS. 1 to 13 will be omitted, for convenience.

FIG. 14 is a view for describing an operation of preparing the cover window 20, from among operations included in the method of manufacturing the display apparatus 1, according to an embodiment. As illustrated in FIG. 14, the cover window 20 may be prepared. By using a jig JIG including a concave surface corresponding to a final shape of the cover window 20, the cover window 20 may be modified to have a flat surface and a curved surface. That is, the jig JIG may be a frame having a shape corresponding to a shape of the display apparatus 1 that is to be finally manufactured. The cover window 20 may be adhere to a concave surface of the jig JIG, and thus, may be modified to have a shape substantially the same as the shape of the concave surface of the jig JIG.

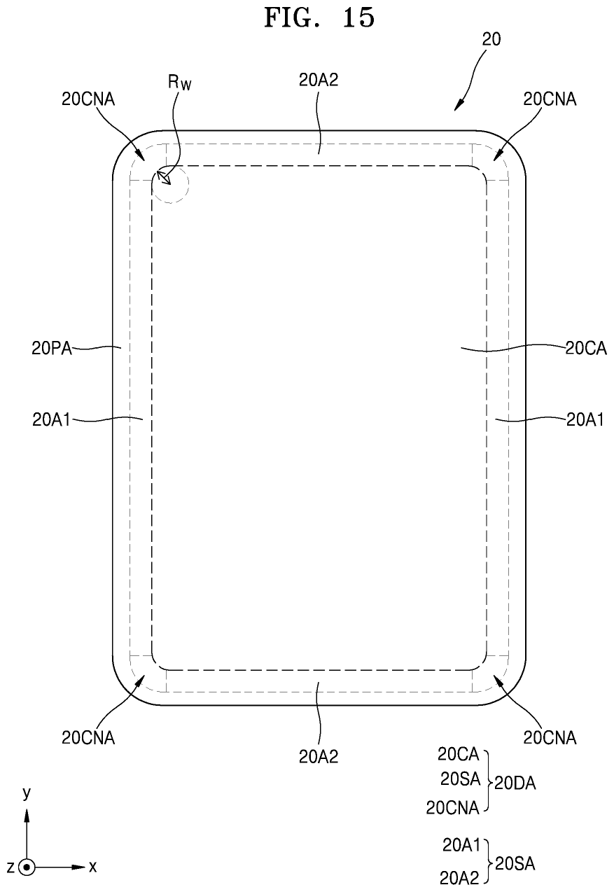

As illustrated in FIG. 15, the cover window 20 that is prepared may include the window central area 20CA, the window side area 20SA, the window corner area 20CNA, and the window peripheral area 20PA. The cover window 20 prepared may have the same shape and structure as the cover window 20 described above with reference to FIG. 3, and thus, any repetitive detailed description thereof is omitted.

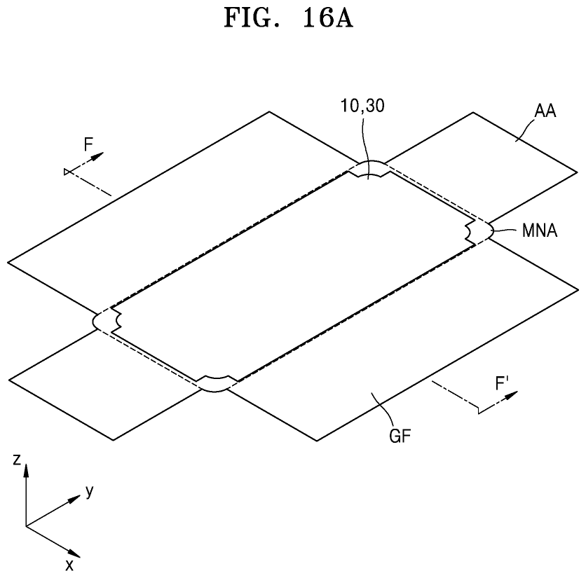

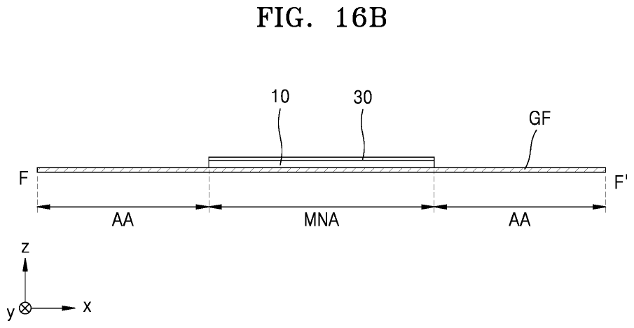

FIGS. 16A and 16B are views for describing an operation of bonding a guide film GF to the display panel 10, from among operations included in the method of manufacturing the display apparatus 1, according to an embodiment. FIG. 16B is a schematic cross-sectional view of the guide film GF, the display panel 10, and the bonding layer 30 of FIG. 16A, taken along line F-F′.

As illustrated in FIGS. 16A and 16B, the guide film GF may be bonded below the display panel 10. The bonding layer 30 may be bonded on an upper surface (in a +z direction) of the display panel 10. That is, the bonding layer 30 may be bonded above (or attached to an upper surface of) the display panel 10, and the guide film GF may be bonded below (or attached to a lower surface of) the display panel 10.

The guide film GF may include a main area MNA and an auxiliary area AA. The auxiliary area AA may be provided in plural, and each of the auxiliary areas AA may extend from an edge of the main area MNA. The guide film GF may be bonded below the display panel 10 in a way such that the display panel 10 corresponds to the main area MNA of the guide film GF. In an embodiment, the guide film GF may be bonded below the display panel 10 in a way such that the entire display panel 10 corresponds to the main area MNA of the guide film GF. That is, the auxiliary area AA of the guide film GF and the display panel 10 may not overlap each other.

The bonding layer 30 may bond the cover window on the display panel 10. The bonding layer 30 may include at least one selected from an OCR, an OCA, and a PSA. Although not shown, a bonding member may be arranged between the display panel 10 and the guide film GF. That is, the guide film GF may be bonded to the display panel 10 by using the bonding member. The bonding member may include a transparent bonding member, such as an OCA film.

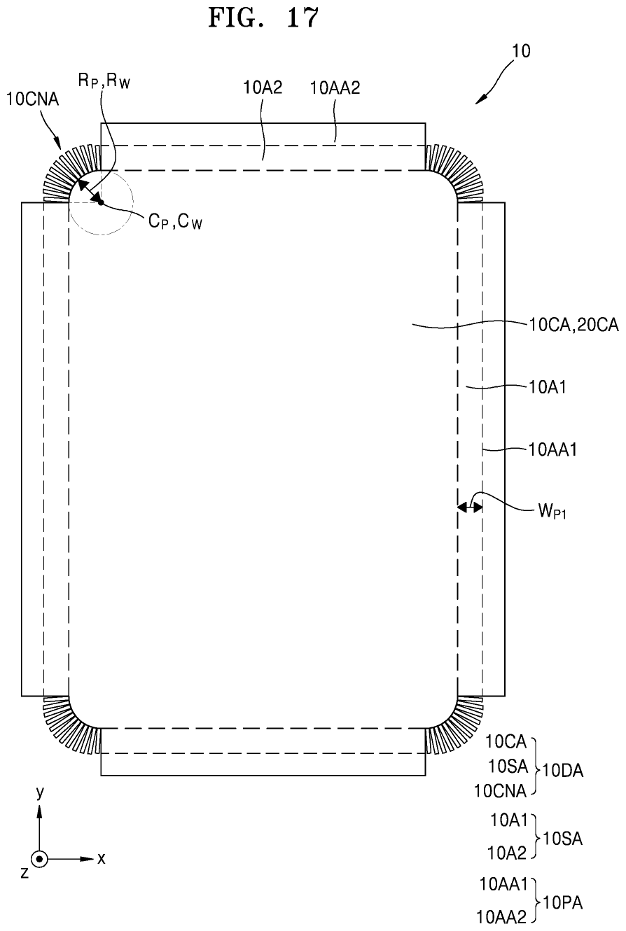

According to an embodiment, the display panel 10 bonded to the guide film GF may include the display panel 10 illustrated in FIG. 17. As illustrated in FIG. 17, the display panel 10 bonded to the guide film GF may include the panel central area 10CA, the panel side area 10SA, the panel corner area 10CNA, and the panel peripheral area 10PA. The display panel 10 bonded to the guide film GF may have the same shape and structure as the display panel 10 described above with reference to FIG. 10, and thus, any repetitive detailed description thereof is omitted.

In a process of bonding the cover window 20 to the display panel 10, to be described below, a significant compressive or tensile stress may be applied to the display panel 10. When the compressive stress or the tensile stress applied to the display panel exceeds a limiting stress of the display panel 10, cracks may occur in the display panel 10. For example, cracks may occur in lines connected to a transistor TFT or each pixel PX included in the display panel 10.

According to an embodiment of the method of manufacturing the display apparatus 1, the display panel 10 may be used, in which the radius of curvature R_{P} of the corner of the panel central area 10CA is the same as the radius of curvature R_{W} of the corner of the window central area 20CA. In such an embodiment, an area of the panel central area 10CA may be the same as an area of the window central area 20CA. That is, the panel central area 10CA and the window central area 20CA may completely overlap each other. Thus, the panel central area 10CA may overlap only the window central area 20CA that is flat. That is, the panel central area 10CA may be arranged below the window central area 20CA. The panel central area 10CA may not overlap areas of the cover window 20, the areas bending based on predetermined axes. In an embodiment, for example, the panel central area 10CA may not overlap the window side area 20SA and the window corner area 20CNA. That is, the panel central area 10CA may not be arranged below the window side area 20SA and may not be arranged below the window corner area 20CNA.

Accordingly, in such an embodiment, even when the cover window 20 is bonded to the display panel 10, a compressive stress or a tensile stress applied to the panel central area 10CA may not exceed a limiting stress. Thus, cracks may not occur in the display panel 10. That is, the possibility of generation of defects during a manufacturing process may be reduced.

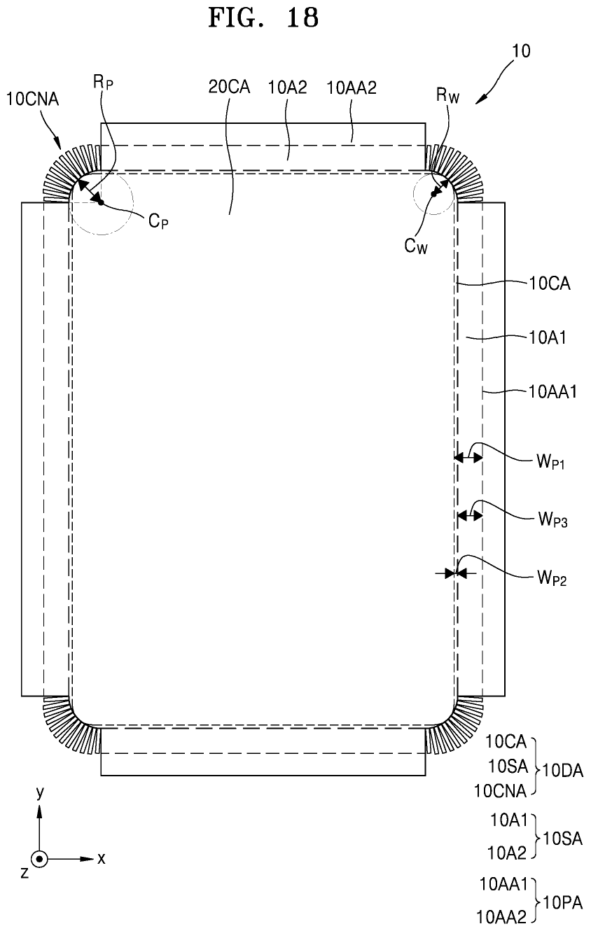

According to an embodiment, the display panel 10 bonded to the guide film GF may include the display panel 10 illustrated in FIG. 18. As illustrated in FIG. 18, the display panel 10 bonded to the guide film GF may include the panel central area 10CA, the panel side area 10SA, the panel corner area 10CNA, and the panel peripheral area 10PA. The display panel 10 bonded to the guide film GF may have the same shape and structure as the display panel 10 described above with reference to FIG. 12, and thus, any repetitive detailed description thereof is omitted.

According to an embodiment of the method of manufacturing the display apparatus 1, the display panel 10 may be used, in which the radius of curvature R_{P} of the corner of the panel central area 10CA is greater than the radius of curvature R_{W} of the corner of the window central area 20CA. As the radius of curvature R_{W} of the corner of the window central area 20CA increases, a portion of the display panel 10, which is overlapping the window side area 20SA and the window corner area 20CNA, may decrease. Thus, the possibility of generation of defects during a manufacturing process may be reduced. As the radius of curvature R_{W} of the corner of the window central area decreases, the shape of the central area CA of the display apparatus 1 may become more similar to a rectangle. Therefore, an aesthetic sense or appeal of the display apparatus 1 may be improved.

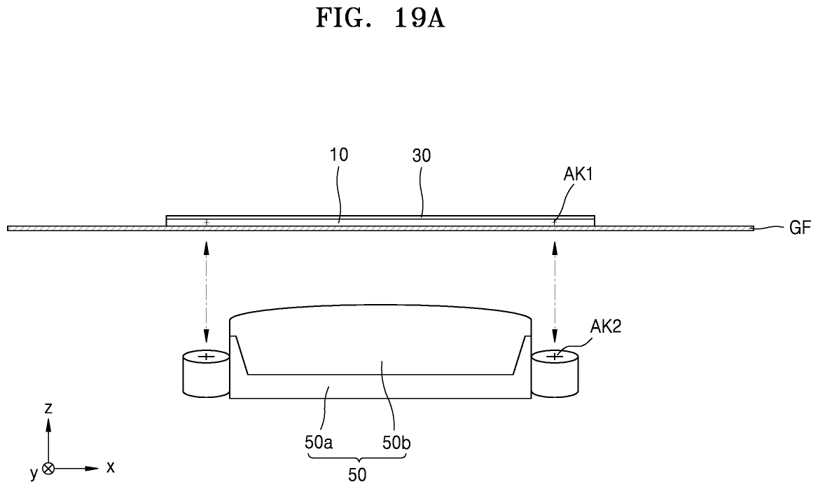

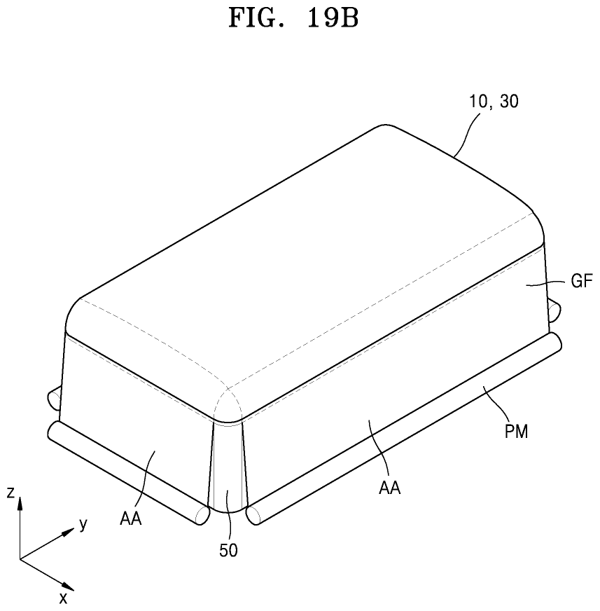

FIGS. 19A and 19B are views for describing an operation of pre-forming the display panel 10, from among operations included in the method of manufacturing the display apparatus 1, according to an embodiment. The shape of the display panel 10 may be modified by applying an external force to the guide film GF as illustrated in FIGS. 19A and 19B. That is, the display panel 10 may be pre-formed by applying an external force to the guide film GF.

First, as illustrated in FIG. 19A, after arranging the display panel 10 in a way such that a lower surface (in a −z direction) of the display panel 10, to which the guide film GF is bonded, faces a pad portion 50, the display panel 10 and the pad portion 50 may be aligned with each other. In an embodiment, the display panel 10 and the pad portion 50 may be aligned with each other such that a first align key AK1 indicated in the display panel 10 and a second align key AK2 indicated in the pad portion 50 correspond to each other.

The pad portion 50 may include a first pad portion 50a and a second pad portion 50b. The first pad portion 50a may support the second pad portion 50b. The second pad portion 50b may include an air pump or may be connected to an air pump. The second pad portion 50b may have a low modulus, and thus, a shape and a volume of the second pad portion 50b may vary according to air pressure through the air pump. Alternatively, the second pad portion 50b may include a diaphragm.

As illustrated in FIG. 19B, the guide film GF bonded to the lower surface (in the −z direction) of the display panel 10 may be mounted on the pad portion 50. A push member PM may be arranged on the guide film GF, and the guide film GF may be made to adhere to a side surface of the pad portion 50 by using the push member PM. In an embodiment, for example, the push members PM may push edges of the guide film GF, and thus, a tensile force may be applied to the guide film GF, and the guide film GF may be modified (or a shape thereof may be changed) according to an external surface of the pad portion 50. Accordingly, the display panel 10 on the guide film GF may be modified. In an embodiment, for example, the display panel 10 may be appropriately bent. However, the bonding layer 30 bonded above the display panel 10 may also be modified. Accordingly, the display panel 10 may be pre-formed to have a shape corresponding to the cover window 20.

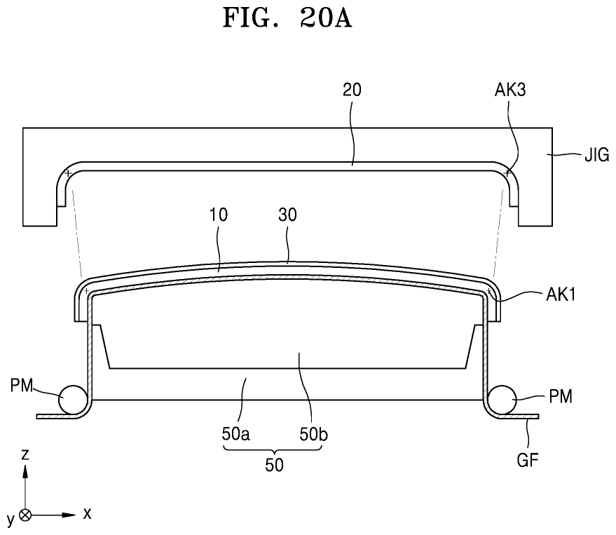

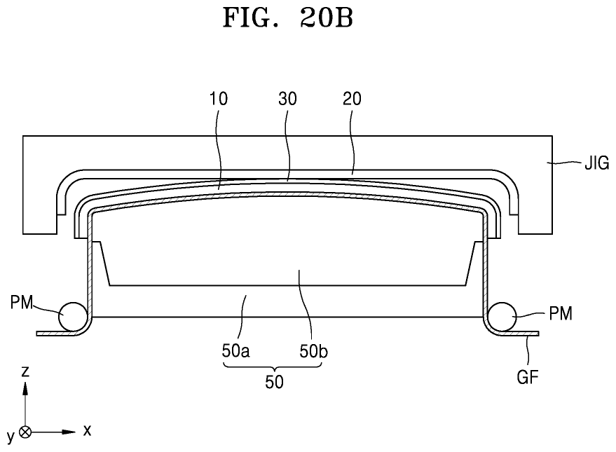

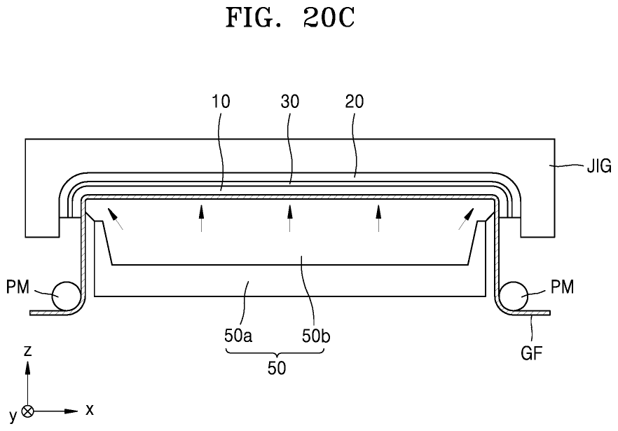

FIGS. 20A to 20C are views for describing an operation of bonding the cover window 20 to the display panel 10, from among operations included in the method of manufacturing the display apparatus 1, according to an embodiment.

First, as illustrated in FIG. 20A, after arranging the display panel 10 such that the upper surface (in the +z direction) of the display panel 10 faces the cover window 20, the display panel 10 and the cover window 20 may be aligned with each other. In an embodiment, the display panel 10 and the cover window 20 may be aligned with each other such that the first align key AK1 indicated in the display panel 10 and a third align key AK3 indicated in the cover window 20 correspond to each other.

Next, as illustrated in FIGS. 20B and 20C, the cover window 20 may be bonded to the display panel 10 by using the pad portion 50. As illustrated in FIG. 20B, initially, a portion of the display panel 10 may be bonded to the cover window 20. The panel central area 10CA of the display panel 10 may be bonded first to the cover window 20.

Next, as illustrated in FIG. 20C, as a shape of the second pad portion 50b of the pad portion 50 changes and a volume of the second pad portion 50b of the pad portion 50 increases, remaining portions of the display panel 10, for example, the panel side area 10SA, the panel corner area 10CNA, and the panel peripheral area 10PA of the display panel 10, may be bonded to the cover window 20. A process of bonding the panel side area 10SA to the cover window 20 and a process of bonding the panel corner area 10CNA to the cover window 20 may be simultaneously performed with each other. In an embodiment, for example, when the panel side area 10SA is bonded to the cover window 20, the panel corner area 10CNA may be naturally bonded to the cover window 20 due to a peripheral external force. In an alternative embodiment, for example, the process of bonding the panel side area 10SA to the cover window 20 and the process of bonding the panel corner area 10CNA to the cover window 20 may be performed at different time points from each other. In an embodiment, for example, after the panel side area 10SA is bonded to the cover window 20, the panel corner area 10CNA may be bonded to the cover window 20. After the cover window 20 is bonded to the display panel 10, the display panel 10 to which the cover window 20 is bonded may be separated from the jig JIG and the pad portion 50.

The cover window 20 may protect the upper surface of the display panel 10. The cover window 20 may protect the display panel 10 by being easily bent according to an external force without cracks, etc. being generated. The cover window 20 may include glass, sapphire, or plastic. In an embodiment, for example, the cover window 20 may include ultra-thin glass (UTG®), the rigidity of which is increased by chemical enhancement or thermal enhancement, or may include CPI. The cover window 20 may have a structure in which a flexible polymer layer is arranged on a surface of a glass substrate or may have a structure including only a polymer layer.

According to an embodiment of the display panel 10, when the radius of curvature R_{P} of the corner of the panel central area 10CA is the same as the radius of curvature R_{W} of the corner of the window central area 20CA of the cover window 20, the first width W_{P1} of the display panel 10 may satisfy the Equation 1. Alternatively, when the radius of curvature R_{P} of the corner of the panel central area 10CA is greater than the radius of curvature R_{W} of the corner of the window central area 20CA of the cover window 20, the second width W_{P2} of the panel central area 10CA may satisfy the Equation 2, and the third width W_{P3} of the first panel area 10A1 may satisfy the Equation 3. Thus, in the display apparatus 1 manufactured according to an embodiment, a length of the portion of the display panel 10, which is arranged below the window corner area 20CNA, and a length of the portion of the display panel 10, which is arranged below the window side area 20SA, with respect to the direction (e.g., the z-axis direction) perpendicular to the panel central area 10CA, may be the same as each other. Accordingly, the display area DA of the display apparatus 1 manufactured according to an embodiment may have a smooth circumference. Thus, the display area DA of the display apparatus 1 manufactured according to the present embodiment may have a proper shape in terms of design and may have an improved aesthetic sense or appeal. That is, a dead space of the display apparatus 1 manufactured according to an embodiment may be reduced, and the display apparatus 1 manufactured according to an embodiment may provide an improved aesthetic sense or appeal.

As described above, according to the embodiments described above, a display apparatus and a method of manufacturing the same, whereby the possibility of generation of defects in a manufacturing process is reduced, and an aesthetic sense or appeal is improved, may be realized.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display apparatus comprising:
a cover window comprising a window central area, a first window area connected to the window central area in a first direction and bent based on an axis extending in a second direction crossing the first direction, a second window area connected to the window central area in the second direction and bent based on an axis extending in the first direction, and a window corner area contacting a corner of the window central area; and
a display panel arranged below the cover window,
wherein, when a radius of curvature of a portion of the display panel arranged to overlap the first window area and bent based on the axis extending in the second direction is R_{B}, and a length of the portion of the display panel arranged to overlap the first window area in a direction perpendicular to a portion of the display panel arranged to overlap the window central area is Z₀, a first width (W_{P1}) of the portion of the display panel in the first direction arranged to overlap the first window area satisfies the following equation:
$${W}_{P 1} = \frac{π {R}_{B}}{2} \times \frac{{cos}^{- 1} \frac{{R}_{B} - {Z}_{0}}{{R}_{B}}}{90} .$$

2. The display apparatus of claim 1, wherein the display panel comprises a panel central area, a first panel area connected to the panel central area in the first direction and bent based on the axis extending in the second direction, a second panel area connected to the panel central area in the second direction and bent based on the axis extending in the first direction, and a panel corner area contacting a corner of the panel central area,
the window central area has a rectangular shape having a chamfered vertex, and
the panel central area has a rectangular shape having a chamfered vertex.

3. The display apparatus of claim 2, wherein a radius of curvature of the corner of the window central area is the same as a radius of curvature of the corner of the panel central area.

4. The display apparatus of claim 2, wherein
the panel central area is arranged to overlap the window central area,
the first panel area is arranged to overlap the first window area,
the second panel area is arranged to overlap the second window area, and
the panel corner area is arranged to overlap the window corner area.

5. The display apparatus of claim 4, wherein the panel central area is arranged not to overlap the first window area, the second window area, and the window corner area.

6. The display apparatus of claim 2, wherein a width of the first panel area in the first direction is the same as the first width.

7. The display apparatus of claim 6, wherein a width of the second panel area in the second direction is the same as the first width.

8. The display apparatus of claim 2, wherein a radius of curvature of the corner of the window central area is less than a radius of curvature of the corner of the panel central area.

9. The display apparatus of claim 8, wherein
a portion of the panel central area is arranged to overlap the window central area,
another portion of the panel central area and the first panel area are arranged to overlap the first window area,
another portion of the panel central area and the second panel area are arranged to overlap the second window area, and
the panel corner area is arranged to overlap the window corner area.

10. The display apparatus of claim 8, wherein, when the radius of curvature of the corner of the window central area is R_{W}, and the radius of curvature of the corner of the panel central area is R_{P}, a second width (W_{P2}) of a portion of the panel central area protruding more in the first direction than the window central area satisfies the following equation:
$${W}_{P 2} = {R}_{P} - {R}_{W} - \frac{{R}_{P} - {R}_{W}}{\sqrt{2}} = - ( 1 - \frac{1}{\sqrt{2}} ) {R}_{W} + ( 1 - \frac{1}{\sqrt{2}} ) {R}_{P} .$$

11. The display apparatus of claim 10, wherein a width of a portion of the panel central area protruding more in the second direction than the window central area is the same as the second width.

12. The display apparatus of claim 10, wherein a third width (W_{P3}) of the first panel area in the first direction satisfies the following equation:
W_{P3}=W_{P1}−W_{P2}.

13. The display apparatus of claim 12, wherein a width of the second panel area in the second direction is the same as the third width.

14. The display apparatus of claim 1, wherein a radius of curvature of a portion of the display panel arranged to overlap the second window area is the same as R_{B},
a length of the portion of the display panel arranged to overlap the second window area in the direction perpendicular to the portion of the display panel arranged to overlap the window central area is the same as Z₀, and
a width of the portion of the display panel arranged to overlap the second window area in the second direction is the same as the first width.

15. A method of manufacturing a display apparatus, the method comprising:
preparing a cover window and a display panel;
bonding a guide film to the display panel;
pre-forming the display panel by applying an external force to the guide film; and
bonding the cover window to the display panel,
wherein the cover window comprises a window central area, a first window area connected to the window central area in a first direction and bent based on an axis extending in a second direction crossing the first direction, a second window area connected to the window central area in the second direction and bent based on an axis extending in the first direction, and a window corner area contacting a corner of the window central area, and
the bonding the cover window comprises bonding the cover window to the display panel in a way such that, when a radius of curvature of a portion of the display panel arranged to overlap the first window area and bent based on the axis extending in the second direction is R_{B}, and a length of the portion of the display panel arranged to overlap the first window area in a direction perpendicular to a portion of the display panel arranged to overlap the window central area is Z₀, a first width (W_{P1}) of the portion of the display panel in the first direction arranged to overlap the first window area satisfies the following equation:
$${W}_{P 1} = \frac{π {R}_{B}}{2} \times \frac{{cos}^{- 1} \frac{{R}_{B} - {Z}_{0}}{{R}_{B}}}{90} .$$

16. The method of claim 15, wherein the display panel comprises a panel central area, a first panel area connected to the panel central area in the first direction and bent based on the axis extending in the second direction, a second panel area connected to the panel central area in the second direction and bent based on the axis extending in the first direction, and a panel corner area contacting a corner of the panel central area,
the window central area has a rectangular shape having a chamfered vertex, and
the panel central area has a rectangular shape having a chamfered vertex.

17. The method of claim 16, wherein the bonding the cover window comprises bonding the cover window to the display panel in a way such that, when a radius of curvature of the corner of the window central area is the same as a radius of curvature of the corner of the panel central area, a width of the first panel area in the first direction is the same as the first width.

18. The method of claim 17, wherein the bonding the cover window comprises bonding the cover window to the display panel in a way such that a width of the second panel area in the second direction is the same as the first width.

19. The method of claim 16, wherein the bonding the cover window comprises bonding the cover window to the display panel in a way such that, when the radius of curvature of the corner of the window central area is R_{W}, and the radius of curvature of the corner of the panel central area is R_{P}, a second width (W_{P2}) of a portion of the panel central area, protruding more in the first direction than the window central area satisfies the following equation:
$${W}_{P 2} = {R}_{P} - {R}_{W} - \frac{{R}_{P} - {R}_{W}}{\sqrt{2}} = - ( 1 - \frac{1}{\sqrt{2}} ) {R}_{W} + ( 1 - \frac{1}{\sqrt{2}} ) {R}_{P} ,$$
and
a third width (W_{P3}) of the first panel area in the first direction satisfies the following equation:
W_{P3}=W_{P1}−W_{P2}.

20. The method of claim 19, wherein the bonding the cover window comprises bonding the cover window to the display panel in a way such that a width of a portion of the panel central area protruding more in the second direction than the window central area is the same as the second width, and a width of the second panel area in the second direction is the same as the third width.
